(19) United States
(12) Patent Application Publication
(10) Pub. No.: US 2026/0076083 A1
(43) Pub. Date: Mar. 12, 2026

(54) ORGANIC ELECTROLUMINESCENT DISPLAY DEVICE

(71) Applicant: FUJIFILM Corporation, Tokyo (JP)

(72) Inventors: Toshihiro KONISHI, Minamiashigara-shi (JP); Mayumi NOJIRI, Minamiashigara-shi (JP)

(73) Assignee: FUJIFILM Corporation, Tokyo (JP)

(21) Appl. No.: 19/389,301

(22) Filed: Nov. 14, 2025

Related U.S. Application Data
(63) Continuation of application No. PCT/JP2024/022151, filed on Jun. 19, 2024.

(30) Foreign Application Priority Data
Jun. 30, 2023 (JP) 2023-108016
Jun. 6, 2024 (JP) 2024-092327

(51) Int. Cl. H10K 59/80

(52) U.S. Cl. CPC H10K 59/8793

(57) ABSTRACT

An organic electroluminescent display device includes a circular polarization plate and an organic electroluminescent display element. The circular polarization plate includes an optically anisotropic layer and a polarizer from an organic electroluminescent display element side. When a ratio of brightness of P-polarized to S-polarized light during white display in a direction in which a polar angle with respect to a normal direction of the display is 60° is determined at each azimuthal angle rotated by 45° with reference to a direction parallel to a transmission axis of the polarizer, an arithmetic mean value of the ratios of the brightness of the P-polarized to the S-polarized light at the azimuthal angles is defined as x and a ratio of in-plane retardation at wavelengths of 600 nm to 440 nm in the optically anisotropic layer is defined as y, x and y satisfy a predetermined relationship.

### CROSS-REFERENCE TO RELATED APPLICATIONS

This application is a Continuation of PCT International Application No. PCT/JP2024/022151 filed on Jun. 19, 2024, which claims priority under 35 U.S.C. § 119 (a) to Japanese Patent Application No. 2023-108016 filed on Jun. 30, 2023 and Japanese Patent Application No. 2024-092327 filed on Jun. 6, 2024. The above applications are hereby expressly incorporated by reference, in their entirety, into the present application.

### BACKGROUND OF THE INVENTION

### 1. Field of the Invention

The present invention relates to an organic electroluminescent display device.

### 2. Description of the Related Art

In the related art, a circular polarization plate has been used in an organic electroluminescent display device (hereinafter, also referred to as an “organic EL display device”) in order to suppress adverse effects due to reflection of external light.

WO2019/022156A discloses an organic EL display device including a circular polarization plate and an organic electroluminescent display element (hereinafter, also referred to as an “organic EL display element”).

### SUMMARY OF THE INVENTION

Recently, there has been a demand for an organic EL display device that exhibits less change in an oblique tint (white) at each azimuthal angle.

The present inventors have studied an organic EL display device obtained by combining a circular polarization plate and an organic EL display element with reference to WO2019/022156A, and therefore have found that the above-mentioned effect may not be obtained depending on the combination of the circular polarization plate and the organic EL display element.

In view of the above circumstances, an object of the present invention is to provide an organic EL display device that exhibits less change in an oblique tint (white) at each azimuthal angle.

As a result of extensive studies to achieve the above object, the present inventors have completed the present invention having the following configuration.
(1) An organic electroluminescent display device comprising:
   a circular polarization plate; and
   an organic electroluminescent display element,
   in which the circular polarization plate includes an optically anisotropic layer and a polarizer from an organic electroluminescent display element side, and
   in a case where a ratio of brightness of P-polarized light to brightness of S-polarized light during white display of the organic electroluminescent display element in a direction in which a polar angle with respect to a normal direction of the organic electroluminescent display element is 60° is determined at each azimuthal angle rotated by 45° with reference to a direction parallel to a transmission axis of the polarizer, an arithmetic mean value of the ratios of the brightness of the P-polarized light to the brightness of the S-polarized light at the azimuthal angles is defined as x and a ratio of an in-plane retardation at a wavelength of 600 nm to an in-plane retardation at a wavelength of 440 nm in the optically anisotropic layer is defined as y, the organic electroluminescent display device satisfies Requirement 1 and Requirement 2.

$$y \leq - 0.155 x + 1.655 \qquad Requirement 1$$

$$y \geq 0. 170 x + 0.980 \qquad Requirement 2$$

The ratio of the brightness of the P-polarized light to the brightness of the S-polarized light is an arithmetic mean value of ratios of the brightness of the P-polarized light to the brightness of the S-polarized light at each wavelength at intervals of 10 nm in a wavelength range of 420 to 680 nm.
(2) The organic electroluminescent display device according to (1), in which the organic electroluminescent display device satisfies Requirement 3 and Requirement 4.

$$y \leq - 0.240 x + 1.74 \qquad Requirement 3$$

$$y \geq 0.26 x + 0.890 \qquad Requirement 4$$

(3) The organic electroluminescent display device according to (1) or (2), in which the optically anisotropic layer is a λ/4 plate.

According to the present invention, it is possible to provide an organic EL display device that exhibits less change in an oblique tint (white) at each azimuthal angle.

### BRIEF DESCRIPTION OF THE DRAWINGS

FIG. 1 is a cross-sectional view of an embodiment of an organic EL display device according to the present invention.

FIG. 2 is a view showing a relationship between an absorption axis of a polarizer and an in-plane slow axis of an optically anisotropic layer in the organic EL display device shown in FIG. 1.

FIG. 3 is a view for describing a state in which light is incident on an optically anisotropic layer and a polarizer.

FIG. 4 is a view showing a relationship between an absorption axis of a polarizer and an in-plane slow axis of an optically anisotropic layer in the organic EL display device shown in FIG. 1.

FIG. 5 is a view for describing a state in which light is incident on an optically anisotropic layer and a polarizer.

FIG. 6 is a view for describing Requirement 1 and Requirement 2.

### DESCRIPTION OF THE PREFERRED EMBODIMENTS

Hereinafter, the present invention will be described in more detail. The description of configuration requirements described below may be made based on representative embodiments of the present invention, but the present invention is not limited to such embodiments.

In the present specification, any numerical range expressed using “to” means a range that includes the numerical values written before and after “to” as the lower limit value and the upper limit value, respectively.

In the present specification, “visible light” means light in a wavelength range of 380 to 780 nm. In addition, in a case where there is no particular description regarding a measurement wavelength, the measurement wavelength is 550 nm.

In the present specification, “in-plane slow axis” means a direction in which an in-plane refractive index is maximum.

In the present specification, Re(λ) and Rth(λ) each represent an in-plane retardation at a wavelength λ and a thickness direction retardation at a wavelength λ. Unless otherwise specified, the wavelength λ is 550 nm.

Re(λ) and Rth(λ) are values measured at a wavelength λ in AxoScan (manufactured by Axometrics, Inc.). By inputting an average refractive index ((nx+ny+nz)/3) and a film thickness (d(μm)) to AxoScan,
slow axis direction) (°

$$Re ( λ ) = R 0 ( λ )$$

$$Rth ( λ ) = ( ( nx + ny ) / 2 - nz ) \times d$$

are calculated.

Although R0(λ) is displayed as a numerical value calculated by AxoScan, R0(λ) means Re(λ).

In the present specification, the refractive indexes nx, ny, and nz are measured using an Abbe refractometer (NAR-4T, manufactured by Atago Co., Ltd.) and a sodium lamp (λ=589 nm) as a light source. In addition, in a case of measuring wavelength dependence, it can be measured using a multi-wavelength Abbe refractometer DR-M2 (manufactured by Atago Co., Ltd.) in combination with a dichroic filter.

In addition, values in the Polymer Handbook (John Wiley & Sons, Inc.) and catalogs of various optical films can be used. Examples of average refractive index values of major optical films are as follows: cellulose acylate (1.48), cycloolefin polymer (1.52), polycarbonate (1.59), polymethylmethacrylate (1.49), and polystyrene (1.59).

In the present specification, “light” refers to an actinic ray or radiation, for example, a bright line spectrum of a mercury lamp, a far ultraviolet ray typified by an excimer laser, an extreme ultraviolet ray (EUV light), an X-ray, an ultraviolet ray, or an electron beam (EB). Above all, an ultraviolet ray is preferable.

In the present specification, the A-plate and the C-plate are defined as follows.

There are two types of A-plates, that is, a positive A-plate (A-plate which is positive) and a negative A-plate (A-plate which is negative). The positive A-plate satisfies a relationship of Expression (A1) and the negative A-plate satisfies a relationship of Expression (A2) in a case where a refractive index in an in-plane slow axis direction of a film (in a direction in which an in-plane refractive index is maximum) is defined as nx, a refractive index in an in-plane direction orthogonal to the in-plane slow axis is defined as ny, and a refractive index in a thickness direction is defined as nz. Note that the positive A-plate has an Rth showing a positive value and the negative A-plate has an Rth showing a negative value.

$$nx > ny \approx nz \qquad Expression ( A1 )$$

$$ny < nx \approx nz \qquad Expression ( A2 )$$

It should be noted that the symbol “˜” encompasses not only a case where the both sides are completely the same as each other but also a case where the both sides are substantially the same as each other. The expression “substantially the same” means that, for example, a case where (ny−nz)× d (in which d is a thickness of a film) is −10 to 10 nm and preferably-5 to 5 nm is also included in “ny≈nz”; and a case where (nx−nz)×d is −10 to 10 nm and preferably −5 to 5 nm is also included in “nx≈nz”.

There are two types of C-plates, that is, a positive C-plate (C-plate which is positive) and a negative C-plate (C-plate which is negative). The positive C-plate satisfies a relationship of Expression (C1) and the negative C-plate satisfies a relationship of Expression (C2). It should be noted that the positive C-plate has an Rth showing a negative value and the negative C-plate has an Rth showing a positive value.

$$nz > nx \approx ny \qquad Expression ( C1 )$$

$$nz < nx \approx ny \qquad Expression ( C2 )$$

It should be noted that the symbol “≈” encompasses not only a case where the both sides are completely the same as each other but also a case where the both sides are substantially the same as each other. The expression “substantially the same” means that, for example, a case where (nx−ny)×d (in which d is a thickness of a film) is 0 to 10 nm and preferably 0 to 5 nm is also included in “nx≈ny”.

In addition, in the present specification, the term “orthogonal” or “parallel” is intended to include a range of errors acceptable in the art to which the present invention pertains. For example, it means that an angle is in an error range of ±5° with respect to an exact angle, and the error with respect to the exact angle is preferably in a range of ±3°.

In addition, in the present specification, the “fixed” state refers to a state in which the alignment of a liquid crystal compound is maintained. Specifically, the “fixed” state is preferably a state in which, in a temperature range of usually 0° C. to 50° C. or in a temperature range of −30° C. to 70° C. under more severe conditions, a layer has no fluidity, and a fixed alignment morphology can be maintained stably without causing any change in the alignment morphology due to an external field or external force.

### [Organic EL Display Device]

Hereinafter, an embodiment of an organic EL display device according to the embodiment of the present invention will be described with reference to the accompanying drawings.

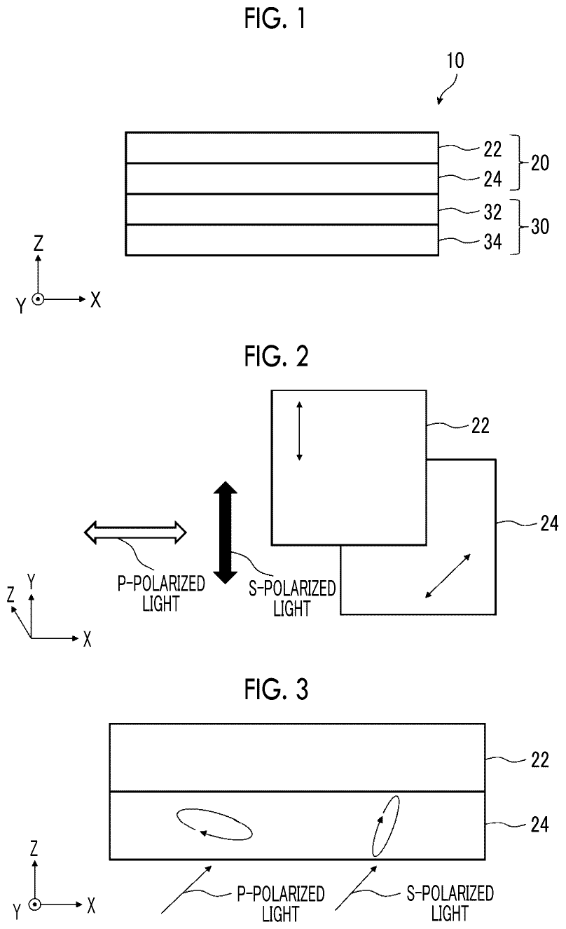

FIG. 1 shows a cross-sectional view of the embodiment of the organic EL display device according to the embodiment of the present invention. It should be noted that the drawings in the present invention are schematic views, and the thickness relationship, the positional relationship, and the like of the layers do not necessarily match the actual ones. The same applies to the drawings which will be described later.

An organic EL display device 10 includes, from a viewing side (upper side in the drawing), a circular polarization plate 20 and an organic EL display element 30. The circular polarization plate 20 includes, from the viewing side, a polarizer 22 and an optically anisotropic layer 24. The organic EL display element 30 includes a polarization adjustment layer 32 and an organic EL substrate 34.

In the aspect of FIG. 1, the organic EL display element 30 includes the polarization adjustment layer 32 and the organic EL substrate 34, but the present invention is not limited to this aspect.

A feature point of the present invention is that, in a case where a ratio of brightness of P-polarized light to brightness of S-polarized light (hereinafter, also referred to as “P/S”) during white display of an organic EL display element in a direction in which a polar angle with respect to a normal direction of the organic EL display element is 60° is determined at each azimuthal angle rotated by 45° with reference to a direction parallel to a transmission axis of a polarizer, an arithmetic mean value of the ratios of the brightness of the P-polarized light to the brightness of the S-polarized light at the azimuthal angles is defined as x (hereinafter, also referred to as “x value”) and a ratio of an in-plane retardation at a wavelength of 600 nm to an in-plane retardation at a wavelength of 440 nm in the optically anisotropic layer is defined as y (hereinafter, also referred to as “y value”), Requirement 1 and Requirement 2 which will be described later are satisfied.

In an organic EL display device including a circular polarization plate and an organic EL display element, light is emitted from an organic EL display element side, and the light that transmits through the circular polarization plate includes P-polarized light and S-polarized light, and the amount of transmitted light that transmits through the circular polarization plate for each of the P-polarized light and the S-polarized light may vary greatly depending on the wavelength and the azimuthal angle, which is thought to result in a large change in oblique tint (white) at each azimuthal angle.

More specifically, the description will be given with reference to FIG. 2 and FIG. 3. FIG. 2 is a view showing a relationship between the absorption axis of the polarizer 22 and the in-plane slow axis of the optically anisotropic layer 24 in the organic EL display device 10 shown in FIG. 1. In FIG. 2, the absorption axis of the polarizer 22 is parallel to the y-axis direction, and the angle formed between the in-plane slow axis of the optically anisotropic layer 24 and the y-axis direction is 45°. FIG. 3 shows an aspect in which light is incident in an oblique direction from a side of the optically anisotropic layer 24 opposite to the polarizer 22 side. In FIG. 3, light is divided into P-polarized light and S-polarized light and the vibration directions thereof are indicated by the black arrow and the white arrow shown in FIG. 2. In a case where such P-polarized light and S-polarized light are incident on the optically anisotropic layer 24 obliquely along the x-axis direction, the polarization state changes. In this case, depending on the value of y which is the ratio of the in-plane retardation of the optically anisotropic layer 24 at a wavelength of 600 nm to the in-plane retardation of the optically anisotropic layer 24 at a wavelength of 440 nm, the incident P-polarized light and S-polarized light are in polarization states in which the absorbances with respect to the absorption axis of the polarizer 22 are different from each other. In the aspect of FIG. 3, the P-polarized light is in a polarization state that is less likely to be absorbed by the polarizer 22.

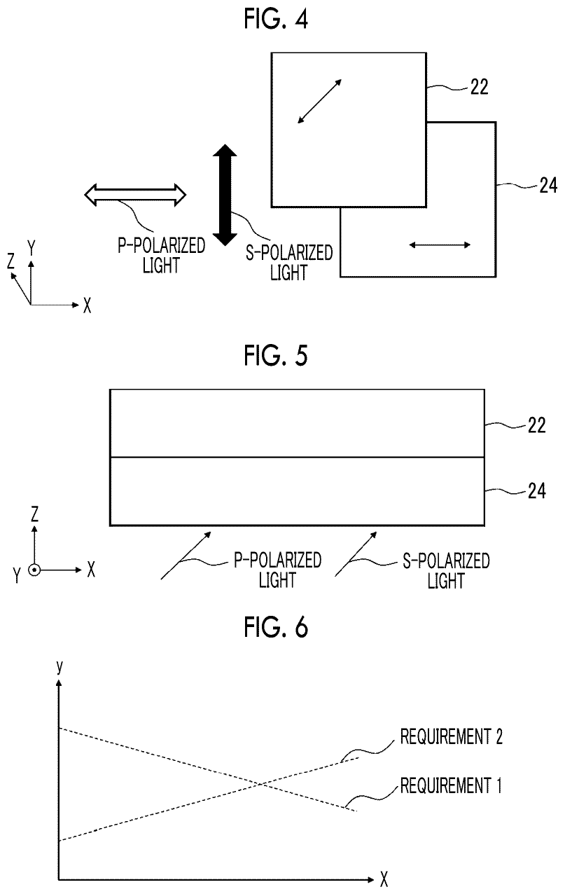

On the other hand, the organic EL display device 10 is rotated by 45° to set a relationship between the absorption axis of the polarizer 22 and the in-plane slow axis of the optically anisotropic layer 24 as shown in FIG. 4. Next, as shown in FIG. 5, light is incident in an oblique direction from a side of the optically anisotropic layer 24 opposite to the polarizer 22 side, as in FIG. 3. In FIG. 5, light is divided into P-polarized light and S-polarized light and the vibration directions thereof are indicated by the black arrow and the white arrow shown in FIG. 4. In a case where such P-polarized light and S-polarized light are obliquely incident on the optically anisotropic layer 24 along the x-axis direction, the polarization state does not change in the relationship with the in-plane slow axis of the optically anisotropic layer 24, and the P-polarized light and the S-polarized light are absorbed by the polarizer 22 at approximately the same reduction rate.

Usually, in a case where P-polarized light and S-polarized light are incident on various members from an oblique direction as shown in FIG. 3 and FIG. 5, S-polarized light is more likely to be reflected at the interface, and P-polarized light is more likely to be included in transmitted light. In this manner, in the case of the aspect shown in FIG. 3 as described above, the absorption of P-polarized light is suppressed more than in the aspect shown in FIG. 5, and as a result, the brightness of the transmitted light that transmits through the polarizer 22 is further increased in the case of the aspect shown in FIG. 3. Therefore, the tint appears to be different depending on the azimuthal angle at which the organic EL display device 10 is viewed. As described above, it has been found that the above-mentioned difference in brightness due to the azimuthal angle may occur depending on the values of x and y which will be described later.

On the other hand, in the present invention, in a case where Requirement 1 and Requirement 2 are satisfied, the amount of change in the amounts of P-polarized light and S-polarized light transmitted through the circular polarization plate depending on the wavelength and the azimuthal angle can be suppressed, so it is considered that the change in oblique tint (white) at each azimuthal angle is further reduced.

In addition, the organic EL display device 10 has the circular polarization plate 20, and therefore also exhibits excellent reflectivity for external light.

Hereinafter, each member of the organic EL display device 10 will be described in more detail.

### <Circular Polarization Plate>

The organic EL display device 10 includes the circular polarization plate 20.

The circular polarization plate 20 includes, from the organic EL display element 30 side, the optically anisotropic layer 24 and the polarizer 22.

### (Polarizer)

The polarizer 22 may be any member that has a function of converting natural light into specific linearly polarized light, and may be, for example, an absorption type polarizer.

Examples of the polarizer 22 include an iodine-based polarizer, a dye-based polarizer using a dichroic substance, and a polyene-based polarizer. The iodine-based polarizer and the dye-based polarizer are produced, for example, by adsorbing iodine or a dichroic dye onto a polyvinyl alcohol, followed by stretching.

A protective film may be disposed on one side or both sides of the polarizer 22.

The thickness of the polarizer 22 is not particularly limited, and is preferably 35 μm or less and more preferably 1 to 25 μm from the viewpoint of excellent handleability and excellent optical properties. The thickness described above makes it possible to achieve thinning of the organic EL display device.

### (Optically Anisotropic Layer)

The optically anisotropic layer 24 is preferably a λ/4 plate. In the aspect shown in FIG. 1, the optically anisotropic layer 24 is preferably a λ/4 plate having a single layer structure, but the aspect thereof is not limited as long as it is an optically anisotropic layer that can constitute a circular polarization plate. For example, the optically anisotropic layer may be a broadband λ/4 plate which is a laminate of a 22 plate and λ/4 plate.

The λ/4 plate is a plate that has a function of converting linearly polarized light having a specific wavelength into circularly polarized light (or converting circularly polarized light into linearly polarized light), and is a plate in which Re(2) satisfies λ/4.

The optically anisotropic layer 24 is preferably a positive A-plate.

The angle formed between the in-plane slow axis of the optically anisotropic layer 24 and the absorption axis of the polarizer 22 is preferably 35° to 55°, more preferably 40° to 50°, and still more preferably 45°.

The Re(550) of the optically anisotropic layer 24 is not particularly limited, and is preferably 110 to 160 nm and more preferably 110 to 150 nm.

The optically anisotropic layer 24 may have either forward wavelength dispersibility or reverse wavelength dispersibility. Above all, the reverse wavelength dispersibility is preferable. The reverse wavelength dispersibility is preferably exhibited in a visible light range.

The thickness of the optically anisotropic layer 24 is preferably 1 to 10 μm and more preferably 1 to 5 μm.

The thickness of the optically anisotropic layer 24 is intended to refer to an average thickness of the optically anisotropic layer 24. The average thickness is determined by measuring the thicknesses of any five or more points of the optically anisotropic layer 24 and arithmetically averaging the measured values.

Hereinafter, in a case where a specific value of a thickness of a layer is shown, the specific value of the thickness is a value obtained by measuring the thicknesses of any five or more points of a certain layer and arithmetically averaging the measured values, as in the above description.

The manufacturing method of the optically anisotropic layer 24 may be, for example, a method of obtaining an optically anisotropic layer by horizontal alignment of a rod-like polymerizable liquid crystal compound. Examples thereof include the manufacturing methods of the positive A-plate disclosed in JP2008-225281A and JP2008-026730A.

The manufacturing method of the optically anisotropic layer having reverse wavelength dispersibility may be, for example, a method of obtaining an optically anisotropic layer by horizontal alignment of a liquid crystal compound having reverse wavelength dispersibility. Here, the liquid crystal compound having “reverse wavelength dispersibility” in the present specification refers to a liquid crystal compound in which an in-plane retardation (Re) value corresponds to or becomes higher than an increase in a measurement wavelength in a case where the Re value in a visible light range of an optically anisotropic layer produced using this liquid crystal compound is measured. Examples of the liquid crystal compound having reverse wavelength dispersibility include the compounds represented by General Formula (I) described in JP2008-297210A (in particular, the compounds described in paragraphs to [0039]), the compounds represented by General Formula (1) described in JP2010-084032A (in particular, the compounds described in paragraphs to [0073]), and the compounds represented by General Formula (1) described in JP2016-081035A (in particular, the compounds described in paragraphs to [0055]).

### <Organic EL Display Element>

The organic EL display element 30 is a display element having a pair of electrodes and an organic light emitting layer sandwiched therebetween.

In addition to the organic light emitting layer, layers such as a hole injection layer, a hole transport layer, an electron injection layer, an electron transport layer, and a protective layer may be provided between the electrodes of the organic EL display element 30, and each of these layers may have other functions. Each layer can be formed using various materials.

The organic EL display element 30 includes the polarization adjustment layer 32 and the organic EL substrate 34.

### (Polarization Adjustment Layer)

The polarization adjustment layer 32 is a layer that adjusts the transmission amounts of P-polarized light and S-polarized light of light that transmits through the polarization adjustment layer 32, and is a layer that can mainly make the transmission amount of P-polarized light larger than the transmission amount of S-polarized light.

The polarization adjustment layer 32 preferably includes an alternating layer in which a layer of high refractive index and a layer of low refractive index are alternately laminated in this order, and a depolarization layer, and the depolarization layer is preferably disposed on the organic EL substrate 34 side.

The light emitted from the organic EL substrate 34 (particularly, the light emitted in an oblique direction) first loses the polarization state thereof in a case of passing through the depolarization layer, thus becoming light in which the ratio of P-polarized light to S-polarized light is equal. In a case where the light transmitted through the depolarization layer (particularly, the light emitted in an oblique direction) transmits through the alternating layer, due to a difference in reflection characteristics between P-polarized light and S-polarized light at an interface between the layer of high refractive index and the layer of low refractive index, the ratio of the P-polarized light and the S-polarized light in the light that transmits through the alternating layer can be controlled by controlling the number of interfaces.

By providing the polarization adjustment layer 32 having the above-mentioned functions, it is easy to adjust the x value to a desired value which will be described later.

The alternating layer is a layer in which a layer of high refractive index and a layer of low refractive index are alternately laminated, and specifically, is a layer consisting of a layer of high refractive index, a layer of low refractive index, a layer of high refractive index, a layer of low refractive index, and the like, and is a layer having each layer in this order. The layer of high refractive index and the layer of low refractive index are preferably disposed to be in contact with each other. That is, it is preferable that no other layer is provided between the layer of high refractive index and the layer of low refractive index.

From the viewpoint of oblique tint, the number of layers of high refractive index laminated in the layer in which a layer of high refractive index and a layer of low refractive index are alternately laminated is preferably 1 to 10, more preferably 1 to 5, still more preferably 1 to 3, and particularly preferably 1 or 2.

In the alternating layer, it is preferable that the number of layers of high refractive index laminated is one more than the number of layers of low refractive index laminated. For example, in a case where a layer of high refractive index, a layer of low refractive index, and a layer of high refractive index are laminated in this order, the number of layers of high refractive index laminated is one more than the number of layers of low refractive index laminated. That is, in the alternating layer, it is preferable that both one surface side and the other surface side are layers of high refractive index.

The refractive index of the layer of high refractive index at a wavelength of 550 nm is preferably 1.7 to 2.7, and more preferably 1.9 to 2.3.

The material constituting the layer of high refractive index is not particularly limited and a known material is adopted. The layer of high refractive index may be an inorganic film or an organic film and is preferably an inorganic film.

In a case where the layer of high refractive index is an inorganic film, the material constituting the inorganic film is preferably silicon nitride. The layer of high refractive index is preferably a layer containing silicon nitride (hereinafter, also referred to as a “silicon nitride layer”).

The silicon nitride layer preferably contains a silicon atom and a nitrogen atom and may also contain an oxygen atom or a hydrogen atom.

In addition, a compositional ratio of the nitrogen atom and the silicon atom in the silicon nitride layer (element ratio: nitrogen atom/silicon atom) is preferably 1.0 to 2.0, and more preferably 1.2 to 1.4.

The silicon nitride layer may contain other inorganic substances in addition to silicon nitride.

The content of the silicon nitride is preferably 90% to 100% by mass, and more preferably 99% to 100% by mass with respect to the total mass of the silicon nitride layer.

The thickness of the silicon nitride layer is preferably 10 nm or more, and more preferably 20 nm or more. The upper limit of the thickness of the silicon nitride layer is preferably 150 nm or less, and more preferably 80 nm or less.

The thickness of the silicon nitride layer is the thickness of a single film, not the total thickness of a plurality of silicon nitride layers.

Examples of the method for forming a silicon nitride layer include a sputtering method, a vacuum vapor deposition method, an ion plating method, and a plasma chemical vapor deposition (CVD) method, and specific examples thereof include the methods for forming a silicon nitride layer described in JP2011-063851A, JP3400324B, JP2002-322561A, and JP2002-361774A.

The layer of low refractive index is a layer having a refractive index lower than that of the layer of high refractive index.

The refractive index of the layer of low refractive index at a wavelength of 550 nm is preferably 1.4 to 1.6, and more preferably 1.45 to 1.55.

The material constituting the layer of low refractive index is not particularly limited and a known material is adopted. The layer of low refractive index may be an inorganic film or an organic film and is preferably an organic film.

The organic film preferably contains a known resin.

Examples of the resin include an epoxy resin, an acrylic resin, a methacrylic resin, a polyester, a methacrylic acid-maleic acid copolymer, a polystyrene, a transparent fluororesin, a polyimide, a fluorinated polyimide, a polyamide, a polyamide imide, a polyetherimide, a cellulose acylate, a polyurethane, a polyether ketone, a polycarbonate, a fluorene ring-modified polycarbonate, an alicyclic ring-modified polycarbonate, and a fluorene ring-modified polyester, among which an acrylic resin or a methacrylic resin is preferable.

The thickness of the organic film is preferably 0.3 to 10 μm.

The thickness of the organic film is the thickness of a single film, not the total thickness of a plurality of organic films.

Examples of the method for forming the organic film include a method of applying a coating liquid containing a monomer, a polymerization initiator, and the like onto a substrate by a known coating method such as roll coating, gravure coating, or spray coating, drying the coating liquid, and curing the coating liquid by heating, ultraviolet irradiation, electron beam irradiation, or the like as necessary. In addition, examples of the method for forming the organic film also include a flash vapor deposition method of evaporating the coating liquid, allowing the vapor to adhere to a substrate, cooling and condensing the vapor to form a liquid film, and curing the film with ultraviolet rays or electron beams to form a film, and a transfer method of transferring a sheet-like organic film.

The alternating layer is preferably a layer in which a silicon nitride layer and an organic film are alternately laminated in this order.

The depolarization layer is not particularly limited as long as it is a layer capable of depolarizing polarized light of light incident on the depolarization layer, and examples thereof include a known high birefringence index resin layer and a known diffusion layer.

Examples of the high birefringence index resin layer include layers containing resins such as a polyethylene terephthalate, an acrylic resin, a methacrylic resin, and a polycarbonate, which have a high birefringence index.

Examples of the diffusion layer include a diffusion layer consisting of a resin and a dispersing agent such as a filler, and a diffusion layer including a layer containing the dispersing agent and a resin layer. Examples of the filler include a mineral filler such as silicon dioxide and an organic filler such as an acrylic resin.

The organic EL substrate 34 may be, for example, a substrate constituting a known organic EL element. Examples of the substrate include the above-mentioned substrate having a pair of electrodes and an organic light emitting layer sandwiched therebetween.

### (Other Layers)

The organic EL display device may have layers other than the above-mentioned members.

Examples of the other layers include an adhesion layer. The organic EL display device preferably has an adhesion layer between the respective members.

Examples of the adhesion layer include a known alignment film, a known pressure sensitive adhesive layer, and a known adhesive layer.

Examples of the method for forming the alignment film include a rubbing treatment of an organic compound (preferably a resin), oblique vapor deposition of an inorganic compound, a method for forming a layer having microgrooves, and accumulation of an organic compound (for example, ω-tricosanoic acid, dioctadecylmethylammonium chloride, or methyl stearate) by a Langmuir-Blodgett method (LB film). In addition, the alignment film may be an alignment film in which an alignment function is generated upon application of an electric field, upon application of a magnetic field, or upon irradiation with light (preferably polarized light).

The alignment film is preferably formed by a rubbing treatment of a polymer.

The alignment film may also be, for example, a photo-alignment film.

The thickness of the alignment film is not particularly limited as long as it can exhibit an alignment function and is preferably 0.01 to 5.0 μm, more preferably 0.05 to 2.0 μm, and still more preferably 0.1 to 0.5 μm.

The alignment film may be peelable from the optically anisotropic layer which will be described later.

### <Requirement 1 and Requirement 2>

It is preferable that the organic EL display device satisfies Requirement 1 and Requirement 2 and satisfies Requirement 3 and Requirement 4.

$$y \leq - 0.155 x + 1.655 \qquad Requirement 1$$

$$y \geq 0. 170 x + 0.980 \qquad Requirement 2$$

$$y \leq - 0.240 x + 1.74 \qquad Requirement 3$$

$$y \geq 0.26 x + 0.890 \qquad Requirement 4$$

As shown in the graph of FIG. 6, a desired effect is exhibited in a region surrounded by the broken line shown as Requirement 1 and the broken line shown as Requirement 2.

### (x Value)

The x value is a value obtained by determining P/S during white display of the organic EL display element in a direction in which the polar angle with respect to the normal direction of the organic EL display element is 60° at each azimuthal angle rotated by 45° with reference to a direction parallel to the transmission axis of the polarizer in the organic EL display device, and arithmetically averaging the values of P/S at each azimuthal angle.

The x value is preferably 1.00 to 2.00, more preferably 1.00 to 1.70, and still more preferably 1.00 to 1.40.

Hereinafter, a method for measuring the x value will be described in detail.

First, each azimuthal angle rotated by 45° is determined with reference to a direction parallel to the transmission axis of the polarizer in the organic EL display device. Examples of the azimuthal angle include 0°, 45°, 90°, 135°, 180°, 225°, 270°, and 315° in a case where the direction parallel to the transmission axis of the polarizer is defined as 0°.

Next, at any of the above-mentioned azimuthal angles, P/S during white display of the organic EL display element is determined in a direction in which the polar angle with respect to the normal direction of the organic EL display element is 60° from the viewing side of the organic EL display device, P/S is measured in the same manner for other azimuthal angles, and then, an arithmetic mean value of the obtained P/S values is defined as the x value. It should be noted that P/S is an arithmetic mean value of the ratios of the brightness of P-polarized light to the brightness of S-polarized light at each wavelength at intervals of 10 nm in a wavelength range of 420 to 680 nm.

The brightness of P-polarized light and the brightness of S-polarized light can be measured using, for example, a spectroradiometer SR-UL1.

Examples of the method of adjusting the x value include adjusting the configuration of the polarization adjustment layer (for example, the number of silicon nitride layers and organic films laminated, and the refractive index of each layer).

### (y Value)

The y value is a ratio of Re(600) to Re(440) (Re(600)/Re(440)) of the optically anisotropic layer.

The y value is a suitable aspect of the above-mentioned x value, and is preferably a value that satisfies Requirement 1 and Requirement 2 and more preferably a value that satisfies Requirement 3 and Requirement 4.

The y value is preferably 1.15 to 1.50, more preferably 1.23 to 1.45, and still more preferably 1.30 to 1.40.

Re(600) is not particularly limited, and is preferably 125 to 175 nm and more preferably 135 to 165 nm.

Re(440) is not particularly limited, and is preferably 85 to 135 nm and more preferably 95 to 125 nm.

The optically anisotropic layer may have either forward wavelength dispersibility or reverse wavelength dispersibility. Above all, the reverse wavelength dispersibility is preferable. The reverse wavelength dispersibility is preferably exhibited in a visible light range.

Although the aspect in which an optically anisotropic layer that is preferably a λ/4 plate is included has been described in the above-mentioned FIG. 1, the organic EL display device according to the embodiment of the present invention may include other optically anisotropic layers.

Examples of the other optically anisotropic layers include an optically anisotropic layer having a phase difference in a thickness direction (preferably a positive C-plate).

The optically anisotropic layer having a phase difference in a thickness direction as described above is preferably disposed between the polarizer and the organic EL display element, and more preferably disposed between the optically anisotropic layer which is a λ/4 plate included in the circular polarization plate and the organic EL display element.

The Rth(550) of the optically anisotropic layer having a phase difference in a thickness direction is not particularly limited, and is preferably −120 to −20 nm and more preferably −100 to −40 nm.

The optically anisotropic layer having a phase difference in a thickness direction may exhibit forward wavelength dispersibility or reverse wavelength dispersibility. The forward wavelength dispersibility and the reverse wavelength dispersibility are preferably exhibited in a visible light range.

The thickness of the optically anisotropic layer having a phase difference in a thickness direction is not particularly limited, and is preferably 10 μm or less, more preferably 0.1 to 5.0 μm, and still more preferably 0.3 to 2.0 μm.

The manufacturing method of the optically anisotropic layer having a phase difference in a thickness direction may be, for example, a method of obtaining an optically anisotropic layer by vertical alignment of a rod-like polymerizable liquid crystal compound. Examples of the manufacturing method of the optically anisotropic layer having a phase difference in a thickness direction include the manufacturing methods of a positive C-plate described in JP2017-187732A, JP2016-053709A, and JP2015-200861A.

The white display of the organic EL display element means that, in a normal direction of the organic EL display element from a viewing side of the organic EL display device, a tint range in a CIE 1931 color system is within a range of 0.293 to 0.333 for CIEx and 0.309 to 0.349 for CIEy.

### [Manufacturing Method of Organic EL Display Device]

The organic EL display device is not particularly limited, and a known method can be used.

For example, a method can be mentioned in which a composition for forming an optically anisotropic layer containing a predetermined polymerizable liquid crystal compound is applied onto a predetermined substrate to form a coating film, the coating film is subjected to an alignment treatment and then subjected to a curing treatment to form a predetermined optically anisotropic layer, the formed optically anisotropic layer and a polarizer are laminated through an adhesion layer to produce a circular polarization plate, and the produced circular polarization plate is then bonded to an organic EL display element.

In a case where the above-mentioned composition for forming an optically anisotropic layer is used, a liquid crystal compound having a polymerizable group (hereinafter, also referred to as a “polymerizable liquid crystal compound”) contained in the composition for forming an optically anisotropic layer is appropriately selected to be an optimum polymerizable liquid crystal compound in accordance with the formation of each optically anisotropic layer.

The content of the polymerizable liquid crystal compound in the composition for forming an optically anisotropic layer is preferably 60% to 99% by mass, and more preferably 70% to 98% by mass with respect to the total solid content of the composition for forming an optically anisotropic layer.

The solid content means a component capable of forming an optically anisotropic layer, excluding a solvent, and even in a case where a component itself is in a liquid state, such a component is regarded as the solid content.

The composition for forming an optically anisotropic layer may contain other components in addition to the polymerizable liquid crystal compound.

Examples of the other components include a chiral agent, a polymerization initiator, a polyfunctional monomer, an alignment control agent (a vertical alignment agent or a horizontal alignment agent), a surfactant, an adhesion improver, a plasticizer, a solvent, and a photo-alignment polymer.

The chiral agent is not particularly limited as long as it is compatible with the liquid crystal compound used in combination.

Examples of the chiral agent include known chiral agents (for example, chiral agents for TN and STN, described in Chapter 3, Section 4-3 of “Liquid Crystal Device Handbook” edited by the 142nd Committee of Japan Society for the Promotion of Science, p. 199, 1989).

The polymerization initiator is selected depending on the type of the polymerization reaction, and examples thereof include a thermal polymerization initiator and a photopolymerization initiator.

The content of the polymerization initiator in the composition for forming an optically anisotropic layer is preferably 0.01% to 20% by mass, and more preferably 0.5% to 10% by mass with respect to the total solid content of the composition for forming an optically anisotropic layer.

Examples of the method for applying the composition for forming an optically anisotropic layer include a curtain coating method, a dip coating method, a spin coating method, a printing coating method, a spray coating method, a slot coating method, a roll coating method, a slide coating method, a blade coating method, a gravure coating method, and a wire bar method.

The alignment treatment can be carried out by drying the coating film at room temperature or by heating the coating film. The liquid crystal phase formed by the alignment treatment can generally be transitioned by a change in temperature or pressure in a case of a thermotropic liquid crystal compound. The liquid crystal phase formed by the alignment treatment can also be transitioned by adjusting a compositional ratio such as an amount of solvent in a case of a lyotropic liquid crystal compound.

Note that the conditions in a case of heating the coating film are not particularly limited, and the heating temperature is preferably 50° C. to 250° C. and more preferably 50° C. to 150° C., and the heating time is preferably 10 seconds to 10 minutes.

In addition, after the coating film is heated, the coating film may be cooled, as necessary, before a curing treatment (light irradiation treatment) which will be described later.

The method of the curing treatment carried out on the coating film in which the polymerizable liquid crystal compound is aligned is not particularly limited, and examples thereof include a light irradiation treatment and a heating treatment. Above all, from the viewpoint of manufacturing suitability, a light irradiation treatment is preferable and an ultraviolet irradiation treatment is more preferable.

The irradiation conditions of the light irradiation treatment are not particularly limited, and an irradiation amount of 50 to 1000 mJ/cm² is preferable.

The atmosphere during the light irradiation treatment is not particularly limited, and a nitrogen atmosphere is preferred.

In a case where another optically anisotropic layer is directly formed on the optically anisotropic layer, for example, a photo-alignment polymer may be unevenly distributed on the surface of the optically anisotropic layer, and the photo-alignment polymer on the surface of the optically anisotropic layer may be aligned by irradiation with light, thereby imparting an alignment restriction force.

### EXAMPLES

Hereinafter, the features of the present invention will be described in more detail with reference to Examples and Comparative Examples. The materials, the amounts and proportions of the materials used, the details of treatments, the procedure of treatments, and the like shown in the following Examples can be appropriately modified without departing from the scope and spirit of the present invention. Accordingly, the scope of the present invention should not be construed as being limited by the specific examples shown below.

### Implementation Procedure 1

### Example 1

### (Production of Optically Anisotropic Layer C1)

A polymerizable liquid crystal composition C1 having the following formulation was prepared.

Polymerizable liquid crystal composition C1

| Mixture A of rod-like liquid crystal | 100 | parts by mass |
|---|---|---|
| compounds shown below | | |
| Acrylate monomer (A-400, manufactured | 4.2 | parts by mass |
| by Shin-Nakamura Chemical Co., Ltd.) | | |
| Polymer A shown below | 2.0 | parts by mass |
| Polymer B shown below | 0.8 | parts by mass |
| Compound A shown below | 1.9 | parts by mass |
| Photopolymerization initiator A shown below | 5.1 | parts by mass |
| Photoacid generator A shown below | 3.0 | parts by mass |
| Methyl isobutyl ketone | 374 | parts by mass |
| Ethyl propionate | 94 | parts by mass |

Mixture A of rod-like liquid crystal compounds (a mixture of the following compounds) Liquid crystal compound (RA):liquid crystal compound (RB):liquid crystal compound (RC)=83:15:2 (mass ratio)

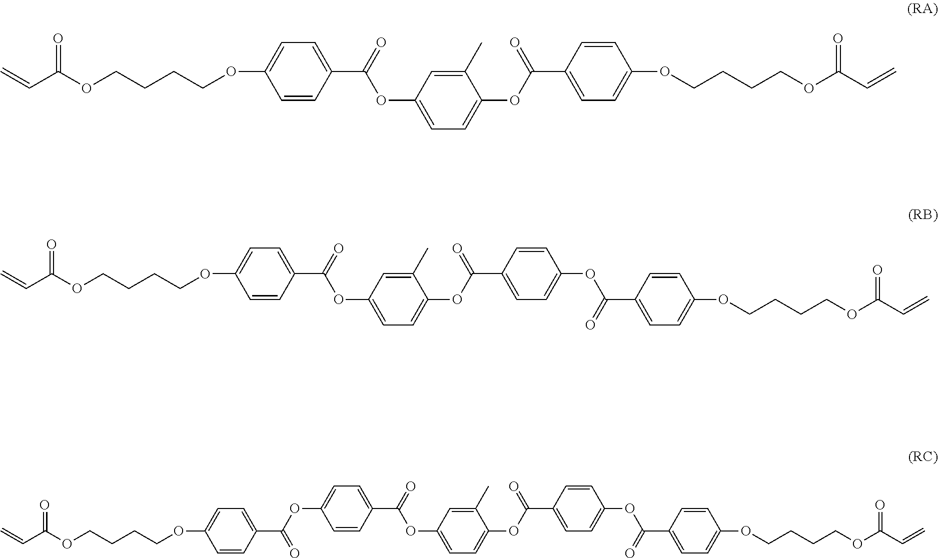

Polymer A (the numerical values in the following formulae indicate the content (% by mass) of each repeating unit with respect to all repeating units in the polymer. The weight-average molecular weight was 57000.)

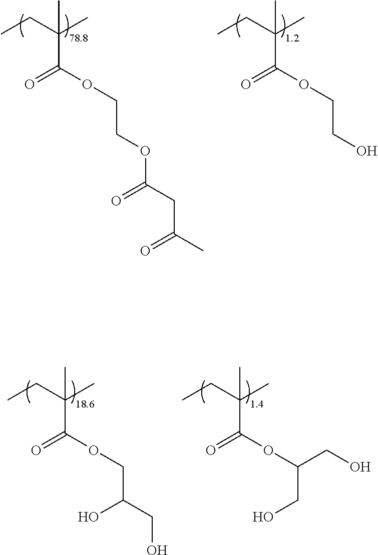

Polymer B (in the following formulae, a to c are a:b:c=37:36:27, and indicate the content (% by mass) of each repeating unit with respect to all repeating units in the polymer. The weight-average molecular weight was 78000.)

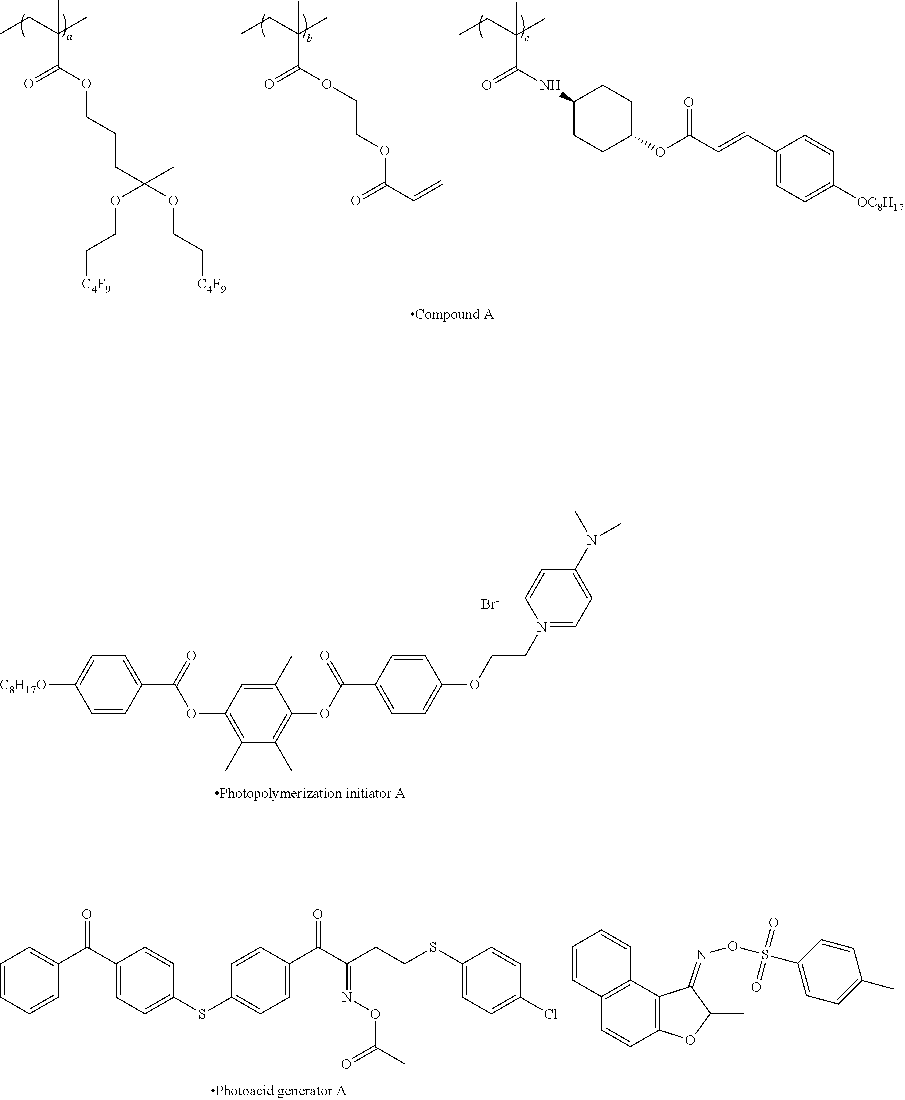

The prepared polymerizable liquid crystal composition C1 was applied onto a cellulose-based polymer film (TG40, manufactured by FUJIFILM Corporation) as a substrate using a #3.0 wire bar, heated at 70° C. for 2 minutes, and irradiated with ultraviolet rays of 150 mJ/cm² under a condition of an oxygen concentration of less than 100 ppm by volume. This was followed by annealing at 120° C. for 1 minute and irradiation with 7.9 mJ/cm² (wavelength: 313 nm) of ultraviolet (UV) light (ultra-high pressure mercury lamp: UL750, manufactured by HOYA Corporation) through a wire grid polarizer at room temperature to impart an alignment function, thereby forming an optically anisotropic layer C1 having a thickness of 0.7 μm. The optically anisotropic layer C1 was a positive C-plate.

### (Production of Optically Anisotropic Layer A1)

A polymerizable liquid crystal composition A1 having the following formulation was prepared.

Polymerizable liquid crystal composition A1

| | | |
|---|---|---|
| Rod-like liquid crystal compound B shown below | 45.4 | parts by mass |
| Rod-like liquid crystal compound C shown below | 21.8 | parts by mass |
| Rod-like liquid crystal compound D shown below | 20.0 | parts by mass |
| Rod-like liquid crystal compound A shown above | 7.8 | parts by mass |
| Compound B shown below | 5.0 | parts by mass |
| Photopolymerization initiator A shown above | 0.5 | parts by mass |
| Leveling agent A shown below | 0.09 | parts by mass |
| Cyclopentanone | 173 | parts by mass |
| Methyl ethyl ketone | 52 | parts by mass |
| Triacetin | 10 | parts by mass |

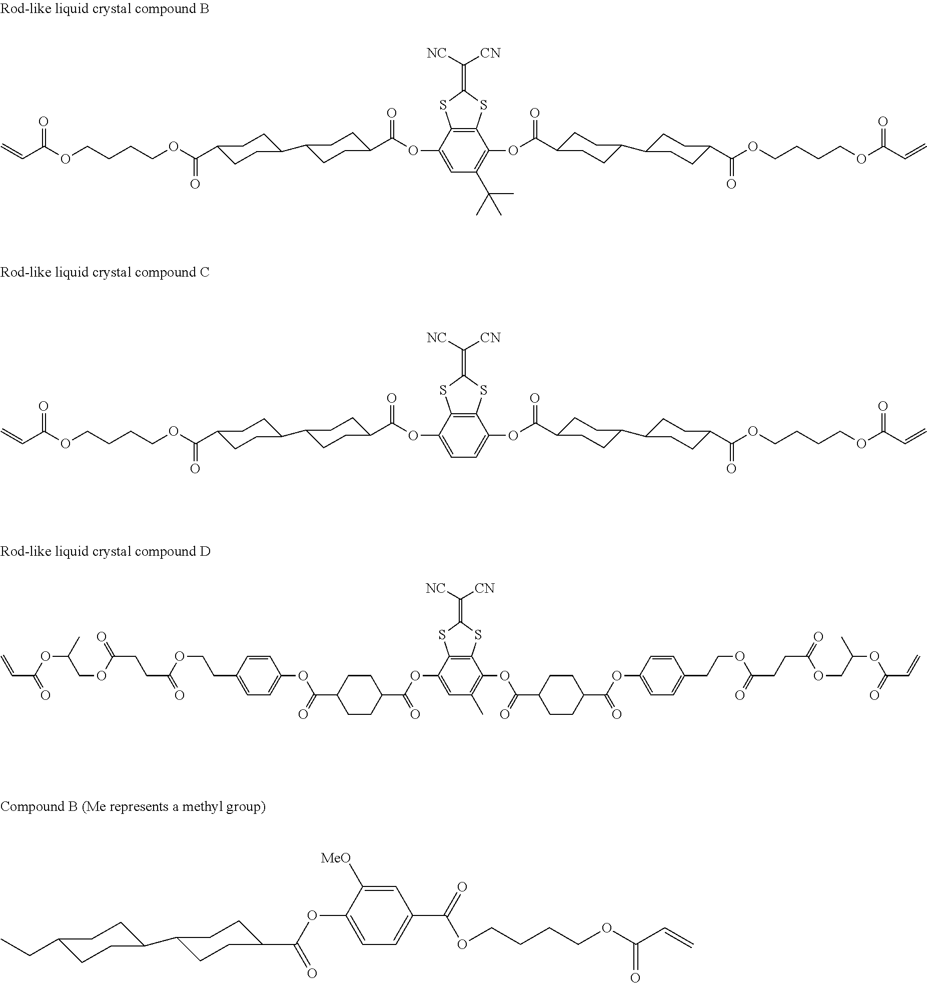

Leveling agent A (the numerical values in the following formulae indicate the content (% by mass) of each repeating unit with respect to all repeating units in the polymer. The weight-average molecular weight was 15000.)

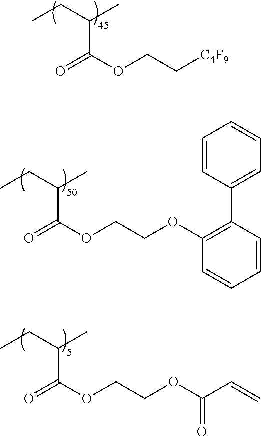

The polymerizable liquid crystal composition A1 was applied onto the above formed optically anisotropic layer C1 using a wire bar coater #6.6 to form a composition layer. The formed composition layer was heated to 120° C. on a hot plate, and then cooled to 60° C. to stabilize the alignment. Thereafter, using an ultra-high pressure mercury lamp and in a nitrogen atmosphere (oxygen concentration of less than 100 ppm by volume), first ultraviolet irradiation (80 mJ/cm²) was carried out at a film temperature kept at 60° C., and then second ultraviolet irradiation (300 mJ/cm²) was carried out at a film temperature kept at 120° C. to immobilize the alignment to form an optically anisotropic layer A1 having a thickness of 3.0 μm, thereby producing an optical laminate.

The optically anisotropic layer A1 was a positive A-plate. The angle of the in-plane slow axis with respect to the film width direction was 45°. The above-mentioned angle is an angle expressed as a positive value in a counterclockwise direction, with the film width direction as a reference (0°) in a case where the optically anisotropic layer A1 disposed on the optically anisotropic layer C1 is observed from the optically anisotropic layer A1 side.

### (Production of Circular Polarization Plate)

A polarizer with a protective film consisting of a norbornene-based resin film/a polarizer P1/a triacetyl cellulose (TAC) film, in which a hard coat layer was formed on one surface thereof, was produced by the method described in Example 4 of JP2021-015294A. The above produced optical laminate was bonded to the TAC film side of the produced polarizer with a protective film through the pressure sensitive adhesive layer B described in Example 4 of JP2021-015294A, such that the optically anisotropic layer A1 side was on the TAC film side of the polarizer with a protective film and the angle formed between the absorption axis of the polarizer and the in-plane slow axis of the optically anisotropic layer A1 was 45°. Thereafter, the cellulose-based polymer film was peeled off at the interface with the optically anisotropic layer C1 to produce a circular polarization plate.

### (Production of P/S Adjustment Layer A)

A silicon nitride layer (silicon nitride film) was produced by the method described in Example 2 of JP2011-063851A, in which a silicon nitride layer is formed using a CVD device, except that the substrate was changed to a PET film (COSMOSHINE SRF, manufactured by Toyobo Co., Ltd.), thereby obtaining a PET film with a silicon nitride layer. The film thickness of the silicon nitride layer was set to 50 nm.

PMMA (15 parts by mass, weight-average molecular weight: 100,000, manufactured by Sigma-Aldrich Co. LLC, methacrylic resin) was added to tetrahydrofuran (85 parts by mass) to prepare a composition X.

The prepared composition X was applied onto the above produced PET film with a silicon nitride layer using a #16 wire bar and heated at 60° C. for 1 minute to form a PMMA film (organic film) having a thickness of 5 μm, thereby obtaining a PET film with a PMMA film and a silicon nitride layer.

A silicon nitride layer was produced by the method described in Example 2 of JP2011-063851A, in which the silicon nitride layer is formed using a CVD device, except that the substrate was changed to the above produced PET film with a PMMA film and a silicon nitride layer. As described above, the silicon nitride layers and PMMA films were repeatedly laminated to produce a P/S adjustment layer A having four laminated silicon nitride layers (the layers between the silicon nitride layers are PMMA films).

### (Production of Organic EL Display Device)

A commercially available organic EL display device (Galaxy S4, manufactured by Samsung Electronics Co., Ltd.) was disassembled, and the bonded polarizer and phase difference film were peeled off to obtain an organic EL substrate. The above produced P/S adjustment layer A was disposed on the obtained organic EL substrate to produce a panel P1. At this time, the P/S adjustment layer A and the organic EL substrate were bonded to each other through a pressure sensitive adhesive (SK2057, manufactured by Soken Chemical & Engineering Co., Ltd.) so that the PET film in the P/S adjustment layer A was in contact with the organic EL substrate. Thereafter, the optically anisotropic layer C1 in the above produced circular polarization plate was bonded to the P/S adjustment layer A side on a surface of the bonded P/S adjustment layer A opposite to the PET film through a pressure sensitive adhesive (SK2057, manufactured by Soken Chemical & Engineering Co., Ltd.) to produce an organic EL display device of Example 1.

### Example 2

An organic EL display device was produced in the same manner as in Example 1, except that the optically anisotropic layer A1 was changed to an optically anisotropic layer A2 produced by the following method.

### (Production of Optically Anisotropic Layer A2)

A polymerizable liquid crystal composition A2 having the following formulation was prepared.

Polymerizable liquid crystal composition A2

| | | |
|---|---|---|
| Rod-like liquid crystal compound B shown above | 45.4 | parts by mass |
| Rod-like liquid crystal compound C shown above | 24.1 | parts by mass |
| Rod-like liquid crystal compound D shown above | 20.0 | parts by mass |
| Rod-like liquid crystal compound A shown above | 5.5 | parts by mass |
| Compound B shown above | 5.0 | parts by mass |
| Photopolymerization initiator A shown above | 0.5 | parts by mass |
| Leveling agent A shown above | 0.09 | parts by mass |
| Cyclopentanone | 173 | parts by mass |
| Methyl ethyl ketone | 52 | parts by mass |
| Triacetin | 10 | parts by mass |

The polymerizable liquid crystal composition A2 was applied onto the above produced optically anisotropic layer C1 using a wire bar coater #7.0 to form a composition layer. The formed composition layer was once heated to 120° C. on a hot plate and then cooled to 60° C. to stabilize the alignment. Thereafter, using an ultra-high pressure mercury lamp and in a nitrogen atmosphere (oxygen concentration of less than 100 ppm by volume), first ultraviolet irradiation (80 mJ/cm²) was carried out at a film temperature kept at 60° C., and then second ultraviolet irradiation (300 mJ/cm²) was carried out at a film temperature kept at 120° C. to immobilize the alignment to form an optically anisotropic layer A2 having a thickness of 3.2 μm, thereby producing an optical laminate.

The optically anisotropic layer A2 was a positive A-plate. The angle of the in-plane slow axis with respect to the film width direction was 45°. The above-mentioned angle is an angle expressed as a positive value in a counterclockwise direction, with the film width direction as a reference (0°) in a case where the optically anisotropic layer A2 disposed on the optically anisotropic layer C1 is observed from the optically anisotropic layer A2 side.

### Example 3

A panel P2 was produced in the same manner as in Example 1, except that the P/S adjustment layer A was changed to a P/S adjustment layer B in which five layers of a silicon nitride film were laminated (layers between the silicon nitride layers were PMMA films), and therefore an organic EL display device was produced.

### Example 4

An organic EL display device was produced in the same manner as in Example 2, except that the panel P1 was changed to the panel P2.

### Example 5

A panel P3 was produced in the same manner as in Example 1, except that the optically anisotropic layer A1 was changed to an optically anisotropic layer A3 produced by the following method, and the P/S adjustment layer A was changed to a P/S adjustment layer C in which three silicon nitride layers were laminated (layers between the silicon nitride layers were PMMA films), and therefore an organic EL display device was produced.

### (Production of Optically Anisotropic Layer A3)

A polymerizable liquid crystal composition A3 having the following formulation was prepared.

Polymerizable liquid crystal composition A3

| | | |
|---|---|---|
| Rod-like liquid crystal compound B shown above | 45.4 | parts by mass |
| Rod-like liquid crystal compound C shown above | 18.6 | parts by mass |
| Rod-like liquid crystal compound D shown above | 20.0 | parts by mass |
| Rod-like liquid crystal compound A shown above | 11.0 | parts by mass |
| Compound B shown above | 5.0 | parts by mass |
| Photopolymerization initiator A shown above | 0.5 | parts by mass |
| Leveling agent A shown above | 0.09 | parts by mass |
| Cyclopentanone | 173 | parts by mass |
| Methyl ethyl ketone | 52 | parts by mass |
| Triacetin | 10 | parts by mass |

The polymerizable liquid crystal composition A3 was applied onto the above produced optically anisotropic layer C1 using a wire bar coater #6.2 to form a composition layer. The formed composition layer was heated to 120° C. on a hot plate, and then cooled to 60° C. to stabilize the alignment. Thereafter, using an ultra-high pressure mercury lamp and in a nitrogen atmosphere (oxygen concentration of less than 100 ppm by volume), first ultraviolet irradiation (80 mJ/cm²) was carried out at a film temperature kept at 60° C., and then second ultraviolet irradiation (300 mJ/cm²) was carried out at a film temperature kept at 120° C. to immobilize the alignment to form an optically anisotropic layer A3 having a thickness of 2.8 μm, thereby producing an optical laminate.

The optically anisotropic layer A3 was a positive A-plate. The angle of the in-plane slow axis with respect to the film width direction was 45°. The above-mentioned angle is an angle expressed as a positive value in a counterclockwise direction, with the film width direction as a reference (0°) in a case where the optically anisotropic layer A3 disposed on the optically anisotropic layer C1 is observed from the optically anisotropic layer A3 side.

### Example 6

An organic EL display device was produced in the same manner as in Example 1, except that the panel P1 was changed to the panel P3.

### Example 7

An organic EL display device was produced in the same manner as in Example 2, except that the panel P1 was changed to the panel P3.

### Example 8

An organic EL display device was produced in the same manner as in Example 5, except that the optically anisotropic layer A3 was changed to an optically anisotropic layer A4 produced by the following method.

### (Production of Optically Anisotropic Layer A4)

A polymerizable liquid crystal composition A4 having the following formulation was prepared.

Polymerizable liquid crystal composition A4

| | | |
|---|---|---|
| Rod-like liquid crystal compound B shown above | 45.4 | parts by mass |
| Rod-like liquid crystal compound C shown above | 27.1 | parts by mass |
| Rod-like liquid crystal compound D shown above | 20.0 | parts by mass |
| Rod-like liquid crystal compound A shown above | 2.5 | parts by mass |
| Compound B shown above | 5.0 | parts by mass |
| Photopolymerization initiator A shown above | 0.5 | parts by mass |
| Leveling agent A shown above | 0.09 | parts by mass |
| Cyclopentanone | 173 | parts by mass |
| Methyl ethyl ketone | 52 | parts by mass |
| Triacetin | 10 | parts by mass |

The polymerizable liquid crystal composition A4 was applied onto the above produced optically anisotropic layer C1 using a wire bar coater #7.4 to form a composition layer. The formed composition layer was heated to 120° C. on a hot plate, and then cooled to 60° C. to stabilize the alignment. Thereafter, using an ultra-high pressure mercury lamp and in a nitrogen atmosphere (oxygen concentration of less than 100 ppm by volume), first ultraviolet irradiation (80 mJ/cm²) was carried out at a film temperature kept at 60° C., and then second ultraviolet irradiation (300 mJ/cm²) was carried out at a film temperature kept at 120° C. to immobilize the alignment to form an optically anisotropic layer A4 having a thickness of 3.4 μm, thereby producing an optical laminate.

The optically anisotropic layer A4 was a positive A-plate. The angle of the in-plane slow axis with respect to the film width direction was 45°. The above-mentioned angle is an angle expressed as a positive value in a counterclockwise direction, with the film width direction as a reference (0°) in a case where the optically anisotropic layer A4 disposed on the optically anisotropic layer C1 is observed from the optically anisotropic layer A4 side.

### Example 9

A panel P4 was produced in the same manner as in Example 5, except that the P/S adjustment layer A was changed to a P/S adjustment layer D in which two silicon nitride layers were laminated (layer between the silicon nitride layers was PMMA film), and therefore an organic EL display device was produced.

### Example 10

An organic EL display device was produced in the same manner as in Example 1, except that the panel P1 was changed to the panel P4.

### Example 11

An organic EL display device was produced in the same manner as in Example 8, except that the panel P3 was changed to the panel P4.

### Example 12

### (Production of Photo-Alignment Film)

The following polymer C (12.0 parts by mass) and the following thermal acid generator A (0.6 parts by mass) were added to a mixed solution containing butyl acetate (74 parts by mass) and methyl ethyl ketone (18 parts by mass) to prepare a composition for forming a photo-alignment film.
Polymer C (weight-average molecular weight: 40,000, numerical values in the following formulae indicate the content (% by mass) of each repeating unit with respect to all repeating units in the polymer)

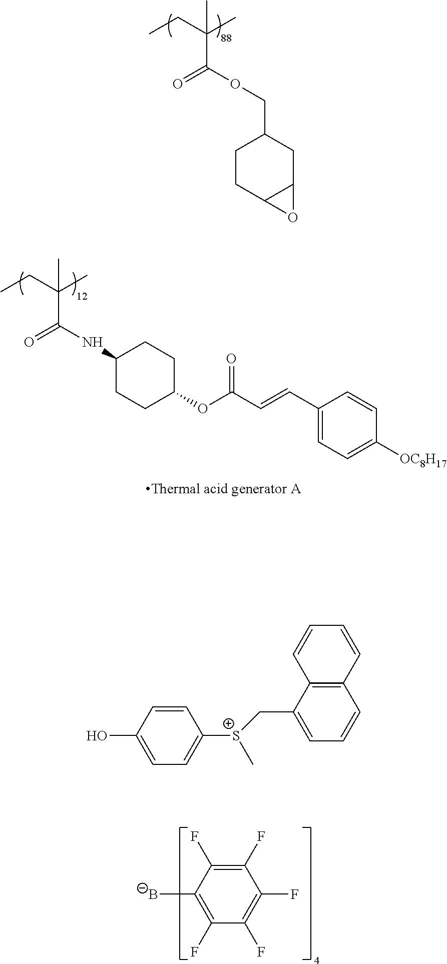

The prepared composition for forming a photo-alignment film was applied onto a cellulose-based polymer film (TG40, manufactured by FUJIFILM Corporation) using a #3.0 wire bar and then dried on a hot plate at 80° C. for 5 minutes to remove the solvent, thereby forming a photoisomerization composition layer having a thickness of 0.5 μm. The obtained photoisomerization composition layer was irradiated with 7.9 mJ/cm² (wavelength: 313 nm) of ultraviolet (UV) light (ultra-high pressure mercury lamp: UL750, manufactured by HOYA Corporation) through a wire grid polarizer to form a photo-alignment film having a thickness of 0.5 μm.

### (Production of Optically Anisotropic Layer A5)

The prepared polymerizable liquid crystal composition A1 was applied onto the above formed photo-alignment film using a wire bar coater #6.6 to form a composition layer. The formed composition layer was heated to 120° C. on a hot plate, and then cooled to 60° C. to stabilize the alignment. Thereafter, using an ultra-high pressure mercury lamp and in a nitrogen atmosphere (oxygen concentration of less than 100 ppm by volume), first ultraviolet irradiation (80 mJ/cm²) was carried out at a film temperature kept at 60° C., and then second ultraviolet irradiation (300 mJ/cm²) was carried out at a film temperature kept at 120° C. to immobilize the alignment to form an optically anisotropic layer A5 having a thickness of 3.0 μm.

The optically anisotropic layer A5 was a positive A-plate. The angle of the in-plane slow axis with respect to the film width direction was 45°. The above-mentioned angle is an angle expressed as a positive value in a counterclockwise direction, with the film width direction as a reference (0°) in a case where the optically anisotropic layer A5 disposed on the photo-alignment film is observed from the optically anisotropic layer A5 side.

### (Production of Circular Polarization Plate)

A polarizer with a protective film consisting of norbornene-based resin film/polarizer P1/TAC film, in which a hard coat layer was formed on one surface thereof, was produced by the method described in Example 4 of JP2021-015294A. The above produced optically anisotropic layer A5 was bonded to the TAC film side of the produced polarizer with a protective film through the pressure sensitive adhesive layer B described in Example 4 of JP2021-015294A, such that the optically anisotropic layer A5 side was on the TAC film side of the polarizer with a protective film and the angle formed between the absorption axis of the polarizer and the in-plane slow axis of the optically anisotropic layer A5 was 45°. Thereafter, the cellulose-based polymer film was peeled off at the interface with the optically anisotropic layer A5 to produce a circular polarization plate.

### (Production of Organic EL Display Device)

The above produced circular polarization plate was bonded to the P/S adjustment layer C of the above produced panel P3 through a pressure sensitive adhesive (SK2057, manufactured by Soken Chemical & Engineering Co., Ltd.) such that the optically anisotropic layer A5 was on the P/S adjustment layer C side, thereby producing an organic EL display device of Example 12.

### Example 13

### (Production of Optically Anisotropic Layer A6)

An optically anisotropic layer A6 (thickness: 44 μm) was produced according to the same procedure as in Example 5 of JP2015-212368A.

The optically anisotropic layer A6 was a positive A-plate. The angle of the in-plane slow axis with respect to the film width direction was 45°. The above-mentioned angle is an angle expressed as a positive value in a counterclockwise direction, with the film width direction as a reference (0°) in a case where the optically anisotropic layer A6 disposed on the photo-alignment film is observed from the optically anisotropic layer A6 side.

### (Production of Circular Polarization Plate)

A polarizer with a protective film consisting of norbornene-based resin film/polarizer P1/TAC film, in which a hard coat layer was formed on one surface thereof, was produced by the method described in Example 4 of JP2021-015294A. The above produced optically anisotropic layer A6 was bonded to the TAC film side of the produced polarizer with a protective film through the pressure sensitive adhesive layer B described in Example 4 of JP2021-015294A such that the angle formed between the absorption axis of the polarizer and the in-plane slow axis of the optically anisotropic layer A6 was 45°, thereby producing a circular polarization plate.

### (Production of Organic EL Display Device)

The above produced circular polarization plate was bonded to the P/S adjustment layer D of the above produced panel P4 through a pressure sensitive adhesive (SK2057, manufactured by Soken Chemical & Engineering Co., Ltd.) such that the optically anisotropic layer A6 was on the P/S adjustment layer D side, thereby producing an organic EL display device of Example 13.

### Example 14

An organic EL display device was produced in the same manner as in Example 12, except that the optically anisotropic layer A5 was changed to an optically anisotropic layer A7 produced by the following method.

### (Production of Optically Anisotropic Layer A7)

A polymerizable liquid crystal composition A7 having the following formulation was prepared.

Polymerizable liquid crystal composition A7

| | | |
|---|---|---|
| Rod-like liquid crystal compound E shown below | 14.0 | parts by mass |
| Rod-like liquid crystal compound F shown below | 83.0 | parts by mass |
| Rod-like liquid crystal compound G shown below | 3.0 | parts by mass |
| Photopolymerization initiator A shown above | 0.5 | parts by mass |
| Leveling agent A shown above | 0.09 | parts by mass |
| N-methyl-2-pyrrolidone | 669 | parts by mass |

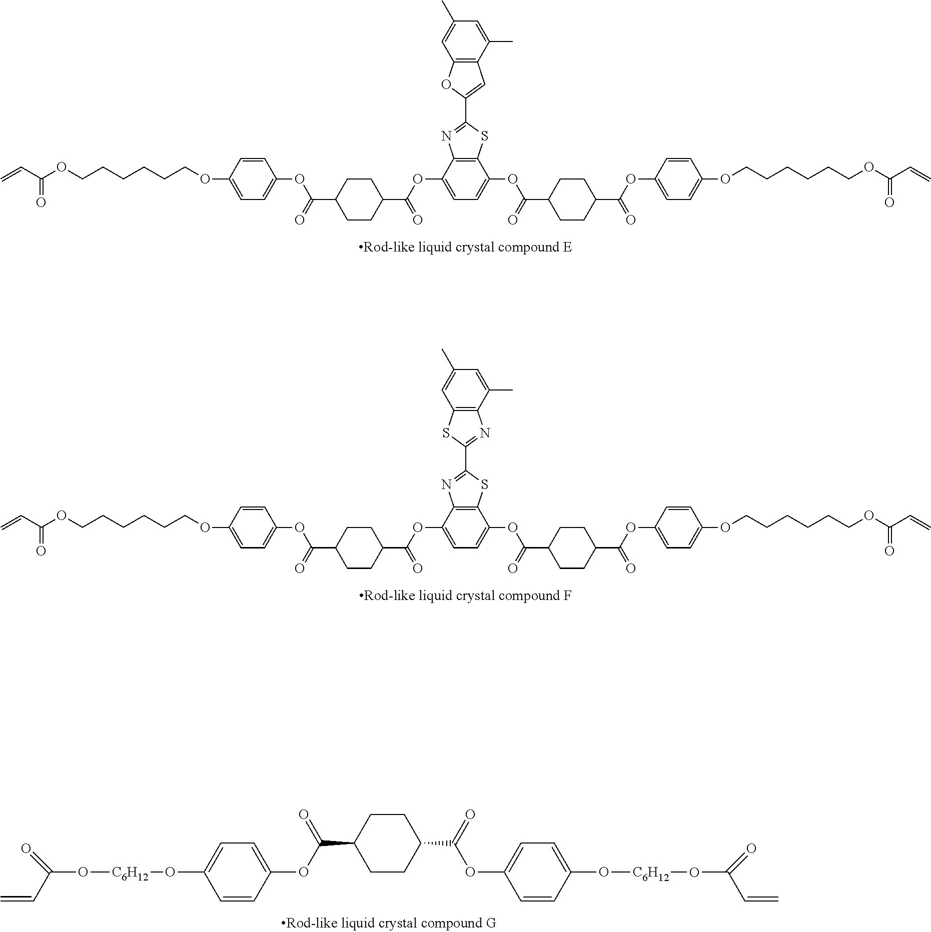

The polymerizable liquid crystal composition A7 was applied onto the above produced photo-alignment film using a wire bar coater #12 to form a composition layer. The formed composition layer was heated to 120° C. on a hot plate, and then cooled to 60° C. to stabilize the alignment. Thereafter, using an ultra-high pressure mercury lamp and in a nitrogen atmosphere (oxygen concentration of less than 100 ppm by volume), first ultraviolet irradiation (80 mJ/cm²) was carried out at a film temperature kept at 60° C., and then second ultraviolet irradiation (300 mJ/cm²) was carried out at a film temperature kept at 120° C. to immobilize the alignment to form an optically anisotropic layer A7 having a thickness of 2.4 μm, thereby producing an optical laminate.

The optically anisotropic layer A7 was a positive A-plate. The angle of the in-plane slow axis with respect to the film width direction was 45°. The above-mentioned angle is an angle expressed as a positive value in a counterclockwise direction, with the film width direction as a reference (0°) in a case where the optically anisotropic layer A7 disposed on the photo-alignment film is observed from the optically anisotropic layer A7 side.

### Comparative Example 1

A panel P5 was produced in the same manner as in Example 1, except that the P/S adjustment layer A was changed to a P/S adjustment layer E in which six silicon nitride layers were laminated (layers between the silicon nitride layers were PMMA films), and therefore an organic EL display device was produced.

### Comparative Example 2

An organic EL display device was produced in the same manner as in Example 2, except that the panel P1 was changed to the panel P5.

### Comparative Example 3

An organic EL display device was produced in the same manner as in Example 1, except that the optically anisotropic layer A1 was changed to the optically anisotropic layer A3.

### Comparative Example 4

An organic EL display device was produced in the same manner as in Example 1, except that the optically anisotropic layer A1 was changed to the optically anisotropic layer A4.

### [Evaluation]

### <P-Polarized Light Brightness and S-Polarized Light Brightness (x Value)>

A polyvinyl alcohol (PVA) film having a thickness of 80 μm was dyed by immersing the film in an iodine aqueous solution having an iodine concentration of 0.05% by mass at 30° C. for 60 seconds. Next, the dyed PVA film was immersed in a boric acid aqueous solution having a boric acid concentration of 4% by mass for 60 seconds, while being machine-direction stretched to 10 times the original length thereof, and the obtained film was then dried at 50° C. for 4 minutes to obtain a linear polarizer having a thickness of 8 μm.

A commercially available cellulose acylate film “TJ25” (manufactured by FUJIFILM Corporation) was prepared, the cellulose acylate film was immersed in a 4.5 mol/L sodium hydroxide aqueous solution at 37° C., and then the sodium hydroxide on the cellulose acylate film was thoroughly washed away with water. Thereafter, the obtained cellulose acylate film was immersed in a 0.05 mol/L diluted sulfuric acid aqueous solution for 30 seconds, and then immersed in water to thoroughly wash away the diluted sulfuric acid aqueous solution. Thereafter, the obtained cellulose acylate film was dried at 70° C. for 15 seconds to produce a polarizer protective film (thickness: 25 μm).

The above produced polarizer protective film was bonded to one surface of the above produced linear polarizer using a polyvinyl alcohol-based adhesive to produce a polarizing plate (thickness: 33 μm) including the linear polarizer and the polarizer protective film disposed on one surface of the linear polarizer.

The polarizer with a protective film was disposed on a light receiving section of a spectroradiometer SR-UL1 (manufactured by TechnoOptis Co., Ltd.) such that the polarizer protective film of the polarizer was on a light receiving section side of the spectroradiometer. At this time, in a case of measuring the P-polarized light brightness, the polarizer was disposed such that the absorption axis of the polarizer was horizontal (parallel to the light emitting surface of the above produced panel), and in a case of measuring the S-polarized light brightness, the polarizer was disposed such that the absorption axis of the polarizer was vertical (perpendicular to the light emitting surface of the above produced panel).

For the above produced organic EL display device, the P-polarized light brightness and the S-polarized light brightness were measured by the above-mentioned measuring method, and the x value was determined.

### <In-Plane Retardation (y Value) at Each Wavelength>

Re(600) and Re(440) of the optically anisotropic layer in each organic EL display device were measured using AxoScan (manufactured by Axometrics, Inc.), and the y value was determined.

### (Display Performance (Oblique Tint) of Organic EL Display Device)

The visibility of the above produced organic EL display device was evaluated in a dark room. The organic EL display device was set to display white and observed at a polar angle of 60° and at intervals of 45° in an azimuthal angle range of 0° to 360°, and the visibility was evaluated according to the following standards.
A: The tint difference at each azimuthal angle is very slight, which is particularly excellent.
B: The tint difference is visually recognized at each azimuthal angle, but the tint difference is small, which is excellent.
C: The tint difference is large at each azimuthal angle, which is not acceptable.

In the table, the column of “SiN lamination number” of “Polarization adjustment layer” refers to the number of SiN (silicon nitride) layers in the P/S adjustment layer. Specifically, in a case where the lamination number is “4”, the P/S adjustment layer has four SiN layers.

In the column of “Requirement 1 to Requirement 4”, “A” is assigned in a case where each requirement is satisfied and “B” is assigned in a case where each requirement is not satisfied.

TABLE 1

| | | Organic EL display device | | | | | | | |
|---|---|---|---|---|---|---|---|---|---|
| | | Circular polarization plate | | | | | | | |
| | | | First | | Second | | | | |
| | | | optically | | optically | | Organic EL display element | | |
| | | | anisotropic | | anisotropic | | | P/S adjustment layer | |
| | | | layer | | layer | | | SiN | |
| | | Polarizer | | Re(550) | | Rth(550) | | lamination | Depolarization |
| | | Type | Type | [nm] | Type | [nm] | Panel | number | layer |
| Example | 1 | P1 | A1 | 141 | C1 | −70 | P1 | 4 | PET |
| Example | 2 | P1 | A2 | 141 | C1 | −70 | P1 | 4 | PET |
| Example | 3 | P1 | A1 | 141 | C1 | −70 | P2 | 5 | PET |
| Example | 4 | P1 | A2 | 141 | C1 | −70 | P2 | 5 | PET |
| Example | 5 | P1 | A3 | 141 | C1 | −70 | P3 | 3 | PET |
| Example | 6 | P1 | A1 | 141 | C1 | −70 | P3 | 3 | PET |
| Example | 7 | P1 | A2 | 141 | C1 | −70 | P3 | 3 | PET |
| Example | 8 | P1 | A4 | 141 | C1 | −70 | P3 | 3 | PET |
| Example | 9 | P1 | A3 | 141 | C1 | −70 | P4 | 2 | PET |
| Example | 10 | P1 | A1 | 141 | C1 | −70 | P4 | 2 | PET |
| Example | 11 | P1 | A4 | 141 | C1 | −70 | P4 | 2 | PET |
| Example | 12 | P1 | A5 | 141 | — | — | P3 | 3 | PET |
| Example | 13 | P1 | A6 | 138 | — | — | P4 | 2 | PET |
| Example | 14 | P1 | A7 | 141 | — | — | P4 | 2 | PET |
| Comparative | 1 | P1 | A1 | 141 | C1 | −70 | P5 | 6 | PET |
| Example | | | | | | | | | |
| Comparative | 2 | P1 | A2 | 141 | C1 | −70 | P5 | 6 | PET |
| Example | | | | | | | | | |
| Comparative | 3 | P1 | A3 | 141 | C1 | −70 | P1 | 4 | PET |
| Example | | | | | | | | | |
| Comparative | 4 | P1 | A4 | 141 | C1 | −70 | P1 | 4 | PET |
| Example | | | | | | | | | |

| | | | | | | | | Evaluation |
|---|---|---|---|---|---|---|---|---|
| | | | | | | | | results |
| | | Organic EL display device | | | | | | Oblique |
| | | x | y | Requirement | Requirement | Requirement | Requirement | tint |
| | | value | value | 1 | 2 | 3 | 4 | (white) |
| Example | 1 | 1.72 | 1.31 | A | A | A | B | B |
| Example | 2 | 1.72 | 1.36 | A | A | B | A | B |
| Example | 3 | 1.89 | 1.31 | A | A | B | B | B |
| Example | 4 | 1.89 | 1.36 | A | A | B | B | B |
| Example | 5 | 1.54 | 1.25 | A | A | A | B | B |
| Example | 6 | 1.54 | 1.31 | A | A | A | A | A |
| Example | 7 | 1.54 | 1.36 | A | A | A | A | A |
| Example | 8 | 1.54 | 1.41 | A | A | B | A | B |
| Example | 9 | 1.36 | 1.25 | A | A | A | A | A |
| Example | 10 | 1.36 | 1.31 | A | A | A | A | A |
| Example | 11 | 1.36 | 1.41 | A | A | A | A | A |
| Example | 12 | 1.54 | 1.31 | A | A | A | A | A |
| Example | 13 | 1.36 | 1.31 | A | A | A | A | A |
| Example | 14 | 1.36 | 1.27 | A | A | A | A | A |
| Comparative | 1 | 2.07 | 1.31 | A | B | B | B | C |
| Example | | | | | | | | |
| Comparative | 2 | 2.07 | 1.36 | B | A | B | B | C |
| Example | | | | | | | | |
| Comparative | 3 | 1.72 | 1.25 | A | B | A | B | C |
| Example | | | | | | | | |
| Comparative | 4 | 1.72 | 1.41 | B | A | B | A | C |
| Example | | | | | | | | |

As shown in Table 1, it was confirmed that the organic EL display device according to the embodiment of the present invention exhibits desired effects.

From the comparison of Examples 1 to 14, it was confirmed that, in a case where Requirement 3 and Requirement 4 were satisfied, the change in oblique tint was smaller. In addition, Examples 15 to 22 will also be provided below.

### Implementation Procedure 2

### Example 15

### (Production of Optical Laminate X1)

The above-mentioned polymerizable liquid crystal composition C1 was applied onto a cellulose-based polymer film (TG40, manufactured by FUJIFILM Corporation) as a substrate using a wire bar, heated at 70° C. for 2 minutes, and irradiated with ultraviolet rays of 150 mJ/cm² under a condition of an oxygen concentration of less than 100 ppm by volume. This was followed by annealing at 120° C. for 1 minute and irradiation with 7.9 mJ/cm² (wavelength: 313 nm) of ultraviolet (UV) light (ultra-high pressure mercury lamp: UL750, manufactured by HOYA Corporation) through a wire grid polarizer at room temperature to impart an alignment function, thereby forming an optically anisotropic layer PC1 having a thickness of 0.55 μm.

The optically anisotropic layer PC1 was a positive C-plate, and had Re(550) of 0 nm and Rth(550) of −55 nm.

A polymerizable liquid crystal composition PA1 having the following formulation was prepared.

Polymerizable liquid crystal composition PA1

| | | |
|---|---|---|
| Mixture A of rod-like liquid crystal | 100 | parts by mass |
| compounds shown above | | |
| Photopolymerization initiator A shown above | 0.5 | parts by mass |
| Leveling agent A shown above | 0.09 | parts by mass |
| Methyl ethyl ketone | 187 | parts by mass |

The polymerizable liquid crystal composition PA1 was applied onto the above produced optically anisotropic layer PC1 using a wire bar coater to form a composition layer. The formed composition layer was heated to 60° C. on a hot plate, and then, in a nitrogen atmosphere (oxygen concentration of less than 100 ppm by volume) using an ultra-high pressure mercury lamp, the film temperature was maintained at 60° C., and the alignment was immobilized by ultraviolet irradiation (300 mJ/cm²) to form an optically anisotropic layer PA1 having a thickness of 0.75 μm, thereby producing an optical laminate X1 (having a configuration of cellulose-based polymer film/optically anisotropic layer PC1/optically anisotropic layer PA1 in this order).

The optically anisotropic layer PA1 was a positive A-plate and had Re(550) of 75 nm and Rth(550) of 37.5 nm, with the angle of the in-plane slow axis with respect to the film width direction being 90°. The above-mentioned angle is an angle expressed as a positive value in a counterclockwise direction, with the film width direction as a reference (0°) in a case where the optically anisotropic layer PA1 disposed on the optically anisotropic layer PC1 is observed from the optically anisotropic layer PA1 side.

### (Production of Optical Laminate X2)

An optical laminate X2 having an optically anisotropic layer A8 on an optically anisotropic layer C2 was produced in the same manner as in the optical laminate in Example 1, except that the thickness of the optically anisotropic layer C1 was changed to 0.4 μm.

### (Production of Circular Polarization Plate)

The coated surface of the optically anisotropic layer PA1 (surface opposite to the optically anisotropic layer PC1) in the above produced optical laminate X1 and the coated surface of the optically anisotropic layer A8 (surface opposite to the optically anisotropic layer C2) in the above produced optical laminate X2 were bonded to each other using a pressure sensitive adhesive in a state where the width directions were aligned, and the cellulose-based polymer film on the optically anisotropic layer PC1 side was peeled off to obtain a laminate composed of cellulose-based polymer film/optically anisotropic layer C2/optically anisotropic layer A8/pressure sensitive adhesive/optically anisotropic layer PA1/optically anisotropic layer PC1 in this order. In the obtained laminate, the surface of the optically anisotropic layer PC1 was bonded to the TAC film side of the polarizer with a protective film shown in Example 1 using a pressure sensitive adhesive, and then the cellulose-based polymer film on the optically anisotropic layer C2 side was peeled off to obtain a circular polarization plate composed of optically anisotropic layer C2/optically anisotropic layer A8/pressure sensitive adhesive/optically anisotropic layer PA1/optically anisotropic layer PC1/pressure sensitive adhesive/TAC/polarizer P1/norbornene-based resin film in this order.

The in-plane slow axis of the optically anisotropic layer PA1 was in a direction of 0° with respect to the absorption axis of the polarizer, and the in-plane slow axis of the optically anisotropic layer A8 was in a direction of 45° with respect to the absorption axis of the polarizer.

The in-plane slow axis of the optically anisotropic layer PA1 was at 0° with respect to the absorption axis of the polarizer, and only the optically anisotropic layer A8 did not change the polarization of the emitted light and substantially affected the display performance (oblique tint) of the organic EL display device (substantially functioned as a λ/4 plate), so the Re(600) and Re(440) of the optically anisotropic layer A8 were measured, and the y value was determined to be 1.31.

(Production of organic EL display device)

Using the panel P3 in the organic EL display device of Example 5, the optically anisotropic layer C2 in the above produced circular polarization plate was bonded to the surface of the P/S adjustment layer C of the panel P3 opposite to the PET film through a pressure sensitive adhesive (SK2057, manufactured by Soken Chemical & Engineering Co., Ltd.) such that the optically anisotropic layer C2 was bonded to the P/S adjustment layer C side, thereby producing an organic EL display device of Example 15.

In a case where the organic EL display device of Example 15 was evaluated by the above-mentioned methods, the results were as follows.
x value: 1.54
y value: 1.31
Requirement 1 to Requirement 4: all satisfied (all rated A)
Oblique tint: rated A

### Example 16

### (Production of Optical Laminate X3)

The polymerizable liquid crystal composition PA1 was applied onto the photo-alignment film produced in the same manner as in Example 12 using a wire bar coater to form a composition layer. The formed composition layer was heated to 60° C. on a hot plate, and then, in a nitrogen atmosphere (oxygen concentration of less than 100 ppm by volume) using an ultra-high pressure mercury lamp, the film temperature was maintained at 60° C., and the alignment was immobilized by ultraviolet irradiation (300 mJ/cm²) to form an optically anisotropic layer PA2 having a thickness of 0.75 μm, thereby producing an optical laminate X3 (having a configuration of cellulose-based polymer film/photo-alignment film/optically anisotropic layer PA2 in this order).

The optically anisotropic layer PA2 was a positive A-plate and had Re(550) of 75 nm and Rth(550) of 37.5 nm, with the angle of the in-plane slow axis with respect to the film width direction being 90°. The above-mentioned angle is an angle expressed as a positive value in a counterclockwise direction, with the film width direction as a reference (0°) in a case where the optically anisotropic layer PA2 produced on the photo-alignment film is observed from the optically anisotropic layer PA2 side.

### (Production of Optical Laminate X4)

An optical laminate X4 having an optically anisotropic layer A9 on an optically anisotropic layer C3 was produced in the same manner as in the optical laminate in Example 1, except that the thickness of the optically anisotropic layer C1 was changed to 1.1 μm.

The optically anisotropic layer C3 was a positive C-plate, and had Re(550) of 0 nm and Rth(550) of −110 nm, and the optically anisotropic layer A9 was a positive A-plate, and Re(550) of 141 nm and Rth(550) of 70.5 nm.

### (Production of Circular Polarization Plate)

The coated surface of the optically anisotropic layer PA2 (surface opposite to the photo-alignment film) in the above produced optical laminate X3 and the coated surface of the optically anisotropic layer A9 (surface opposite to the optically anisotropic layer C3) in the above produced optical laminate X4 were bonded to each other using a pressure sensitive adhesive in a state where the width directions were aligned, and the cellulose-based polymer film and the photo-alignment film on the optically anisotropic layer PA2 side were peeled off to obtain a laminate composed of cellulose-based polymer film/optically anisotropic layer C3/optically anisotropic layer A9/pressure sensitive adhesive/optically anisotropic layer PA2 in this order. In the obtained laminate, the surface of the optically anisotropic layer PA2 was bonded to the TAC film side of the polarizer with a protective film shown in Example 1 using a pressure sensitive adhesive, and then the cellulose-based polymer film on the optically anisotropic layer C3 side was peeled off to obtain a circular polarization plate composed of optically anisotropic layer C3/optically anisotropic layer A9/pressure sensitive adhesive/optically anisotropic layer PA2/pressure sensitive adhesive/TAC/polarizer P1/norbornene-based resin film in this order.

The in-plane slow axis of the optically anisotropic layer PA2 was in a direction of 0° with respect to the absorption axis of the polarizer, and the in-plane slow axis of the optically anisotropic layer A9 was in a direction of 45° with respect to the absorption axis of the polarizer.

The in-plane slow axis of the optically anisotropic layer PA2 was at 0° with respect to the absorption axis of the polarizer, and only the optically anisotropic layer A9 did not change the polarization of the emitted light and substantially affected the display performance (oblique tint) of the organic EL display device (substantially functioned as a λ/4 plate), so the Re(600) and Re(440) of the optically anisotropic layer A9 were measured, and the y value was determined to be 1.31.

### (Production of Organic EL Display Device)

Using the panel P3 in the organic EL display device of Example 5, the optically anisotropic layer C3 in the above produced circular polarization plate was bonded to the surface of the P/S adjustment layer C of the panel P3 opposite to the PET film through a pressure sensitive adhesive (SK2057, manufactured by Soken Chemical & Engineering Co., Ltd.) such that the optically anisotropic layer C3 was bonded to the P/S adjustment layer C side, thereby producing an organic EL display device of Example 16.

In a case where the organic EL display device of Example 16 was evaluated by the above-mentioned methods, the results were as follows.
x value: 1.54
y value: 1.31
Requirement 1 to Requirement 4: all satisfied (all rated A)
Oblique tint: rated A

### Example 17

### (Production of Optical Laminate X5)

An optical laminate X5 having an optically anisotropic layer PC1 and an optically anisotropic layer PA3 (having a configuration of cellulose-based polymer film/optically anisotropic layer PC1/optically anisotropic layer PA3 in this order) was produced in the same manner as in the optical laminate X1 of Example 15, except that the in-plane slow axis direction (alignment axis angle of the liquid crystal compound) of the optically anisotropic layer PA1 was changed to 45° and the thickness was changed to 0.4 μm. The above-mentioned angle is an angle expressed as a positive value in a counterclockwise direction, with the film width direction as a reference (0°) in a case where the optically anisotropic layer PA3 disposed on the optically anisotropic layer PC1 is observed from the optically anisotropic layer PA3 side.

### (Production of Optical Laminate X6)

An optically anisotropic layer C4 was produced in the same manner as in the optically anisotropic layer C1 of Example 1, except that the thickness of the optically anisotropic layer C1 was changed to 0.55 μm. In addition, an optical laminate X6 having an optically anisotropic layer A10 on the optically anisotropic layer C4 was produced in the same manner as that for the optical laminate in Example 1, except that the polymerizable liquid crystal composition A1 of Example 1 was changed to the following polymerizable liquid crystal composition A10 and an optically anisotropic layer A10 having a thickness of 2.9 μm was produced.

Polymerizable liquid crystal composition A10

| | | |
|---|---|---|
| Rod-like liquid crystal compound B shown above | 35.0 | parts by mass |
| Rod-like liquid crystal compound C shown above | 35.0 | parts by mass |
| Rod-like liquid crystal compound A shown above | 17.0 | parts by mass |
| Compound B shown above | 13.0 | parts by mass |
| Photopolymerization initiator A shown above | 0.5 | parts by mass |
| Leveling agent A shown above | 0.09 | parts by mass |
| Cyclopentanone | 173 | parts by mass |
| Methyl ethyl ketone | 52 | parts by mass |
| Triacetin | 10 | parts by mass |

The optically anisotropic layer C4 was a positive C-plate, and had Re(550) of 0 nm and Rth(550) of −55 nm, and the optically anisotropic layer A10 was a positive A-plate, and had Re(550) of 180 nm and Rth(550) of 90.0 nm, with the angle of the in-plane slow axis with respect to the film width direction being 45°. The above-mentioned angle is an angle expressed as a positive value in a counterclockwise direction, with the film width direction as a reference (0°) in a case where the optically anisotropic layer A10 disposed on the optically anisotropic layer C4 is observed from the optically anisotropic layer A10 side.

### (Production of Circular Polarization Plate)

The coated surface of the optically anisotropic layer PA3 (surface opposite to the optically anisotropic layer PC1) in the above produced optical laminate X5 and the coated surface of the optically anisotropic layer A10 (surface opposite to the optically anisotropic layer C4) in the above produced optical laminate X6 were bonded to each other using a pressure sensitive adhesive in a state where the width directions were aligned, and the cellulose-based polymer film on the optically anisotropic layer PC1 side was peeled off to obtain a laminate composed of cellulose-based polymer film/optically anisotropic layer C4/optically anisotropic layer A10/pressure sensitive adhesive/optically anisotropic layer PA3/optically anisotropic layer PC1 in this order. The surface of the optically anisotropic layer PC1 was bonded to the TAC film side of the polarizer with a protective film shown in Example 1 using a pressure sensitive adhesive, and then the cellulose-based polymer film on the optically anisotropic layer C4 side was peeled off to obtain a circular polarization plate composed of optically anisotropic layer C4/optically anisotropic layer A10/pressure sensitive adhesive/optically anisotropic layer PA3/optically anisotropic layer PC1/pressure sensitive adhesive/TAC/polarizer P1/norbornene-based resin film in this order.

The in-plane slow axis of the optically anisotropic layer PA3 was in a direction of −45° with respect to the absorption axis of the polarizer, and the in-plane slow axis of the optically anisotropic layer A10 was in a direction of 45° with respect to the absorption axis of the polarizer. In a case where Re(600) and Re(440) of the laminate of the optically anisotropic layer A10 and the optically anisotropic layer PA3 were measured, the y value was determined to be 1.33.

### (Production of Organic EL Display Device)

Using the panel P3 in the organic EL display device of Example 5, the optically anisotropic layer C4 in the above produced circular polarization plate was bonded to the surface of the P/S adjustment layer C of the panel P3 opposite to the PET film through a pressure sensitive adhesive (SK2057, manufactured by Soken Chemical & Engineering Co., Ltd.) such that the optically anisotropic layer C4 was bonded to the P/S adjustment layer C side, thereby producing an organic EL display device of Example 17.

In a case where the organic EL display device of Example 17 was evaluated by the above-mentioned methods, the results were as follows.
x value: 1.54
y value: 1.33
Requirement 1 to Requirement 4: all satisfied (all rated A)
Oblique tint: rated A

### Example 18

### (Production of Optical Laminate X7)

An optically anisotropic layer PA4 was formed in the same manner as that for the optically anisotropic layer PA2 of Example 16, except that the thickness of the optically anisotropic layer PA1 was changed to 0.4 μm and the in-plane slow axis direction (alignment axis angle of the liquid crystal compound) was changed to 45°, thereby producing an optical laminate X7 (having a configuration of cellulose-based polymer film/photo-alignment film/optically anisotropic layer PA4 in this order). The above-mentioned angle is an angle expressed as a positive value in a counterclockwise direction, with the film width direction as a reference (0°) in a case where the optically anisotropic layer PA4 produced on the photo-alignment film is observed from the optically anisotropic layer PA4 side.

### (Production of Optical Laminate X8)

An optical laminate X8 having an optically anisotropic layer A11 on an optically anisotropic layer C5 was produced in the same manner as in the optical laminate X6 of Example 17, except that the thickness of the optically anisotropic layer C4 was changed to 1.1 μm.

The optically anisotropic layer C5 was a positive C-plate, and had Re(550) of 0 nm and Rth(550) of −110 nm, and the optically anisotropic layer A11 was a positive A-plate, and had Re(550) of 180 nm and Rth(550) of 90.0 nm.

### (Production of Circular Polarization Plate)

The coated surface of the optically anisotropic layer PA4 (surface opposite to the photo-alignment film) in the above produced optical laminate X7 and the coated surface of the optically anisotropic layer A11 (surface opposite to the optically anisotropic layer C5) in the above produced optical laminate X8 were bonded to each other using a pressure sensitive adhesive in a state where the width directions were aligned, and the cellulose-based polymer film and the photo-alignment film on the optically anisotropic layer PA4 side were peeled off to obtain a laminate composed of cellulose-based polymer film/optically anisotropic layer C5/optically anisotropic layer A11/pressure sensitive adhesive/optically anisotropic layer PA4 in this order. In the obtained laminate, the surface of the optically anisotropic layer PA4 was bonded to the TAC film side of the polarizer with a protective film shown in Example 1 using a pressure sensitive adhesive, and then the cellulose-based polymer film on the optically anisotropic layer C5 side was peeled off to obtain a circular polarization plate composed of optically anisotropic layer C5/optically anisotropic layer A11/pressure sensitive adhesive/optically anisotropic layer PA4/pressure sensitive adhesive/TAC/polarizer P1/norbornene-based resin film in this order.

The in-plane slow axis of the optically anisotropic layer PA4 was in a direction of −45° with respect to the absorption axis of the polarizer, and the in-plane slow axis of the optically anisotropic layer A11 was in a direction of 45° with respect to the absorption axis of the polarizer. In a case where Re(600) and Re(440) of the laminate of the optically anisotropic layer A11 and the optically anisotropic layer PA4 were measured, the y value was determined to be 1.33.

### (Production of Organic EL Display Device)

Using the panel P3 in the organic EL display device of Example 5, the optically anisotropic layer C5 in the above produced circular polarization plate was bonded to the surface of the P/S adjustment layer C of the panel P3 opposite to the PET film through a pressure sensitive adhesive (SK2057, manufactured by Soken Chemical & Engineering Co., Ltd.) such that the optically anisotropic layer C5 was bonded to the P/S adjustment layer C side, thereby producing an organic EL display device of Example 18.

In a case where the organic EL display device of Example 18 was evaluated by the above-mentioned methods, the results were as follows.
x value: 1.54
y value: 1.33
Requirement 1 to Requirement 4: all satisfied (all rated A)
Oblique tint: rated A

### Example 19

### (Production of Optical Laminate X9)

A polymerizable liquid crystal composition NC1 containing a disk-like liquid crystal compound having the following formulation was applied onto a cellulose-based polymer film (TG40, manufactured by FUJIFILM Corporation) using a geeser coating machine to form a composition layer. Thereafter, both ends of the film were held, a cooling plate (9° C.) was placed on the side of the surface on which the coating film of the film was formed so that the distance from the film was 5 mm, a heater (110° C.) was placed on the side opposite to the surface on which the coating film of the film was formed so that the distance from the film was 5 mm, and the film was dried for 90 seconds.

The obtained film was then heated with hot air at 116° C. for 1 minute, and irradiated with ultraviolet rays at an irradiation amount of 150 mJ/cm² using a 365 nm ultraviolet-light emitting diode (UV-LED) while purging with nitrogen so that the atmosphere had an oxygen concentration of 100 ppm by volume or less. After that, the obtained coating film was annealed with hot air at 115° C. for 25 seconds, and irradiated with 7.9 mJ/cm² (wavelength: 313 nm) of UV light (ultra-high pressure mercury lamp: UL750, manufactured by HOYA Corporation) through a wire grid polarizer at room temperature to impart an alignment control ability to the surface, thereby forming an optically anisotropic layer NC1.

The film thickness of the optically anisotropic layer NC1 was 0.75 μm. The optically anisotropic layer NC1 was a negative C-plate, and had Re(550) of 0 nm and Rth(550) of −75 nm. It was confirmed that an average tilt angle of a disc plane of the disk-like liquid crystal compound with respect to the film surface was 0°, and the disk-like liquid crystal compound was horizontally aligned with respect to the film surface.

Polymerizable liquid crystal composition NC1

| | | |
|---|---|---|
| Disk-like liquid crystal compound A shown below | 4.0 | parts by mass |
| Disk-like liquid crystal compound B shown below | 2.0 | parts by mass |
| Disk-like liquid crystal compound C shown below | 95.0 | parts by mass |
| Ethylene oxide-modified trimethylolpropane | 12.0 | parts by mass |
| triacrylate (V# 360, manufactured by Osaka | | |
| Organic Chemical Industry Ltd.) | | |
| Photopolymerization initiator A shown above | 3.0 | parts by mass |
| Photoacid generator A shown above | 3.0 | parts by mass |
| Photo-alignment polymer A shown below | 1.0 | parts by mass |
| Methyl ethyl ketone | 208 | parts by mass |
| Ethyl propionate | 520 | parts by mass |
| Methyl ethyl ketone | 12 | parts by mass |

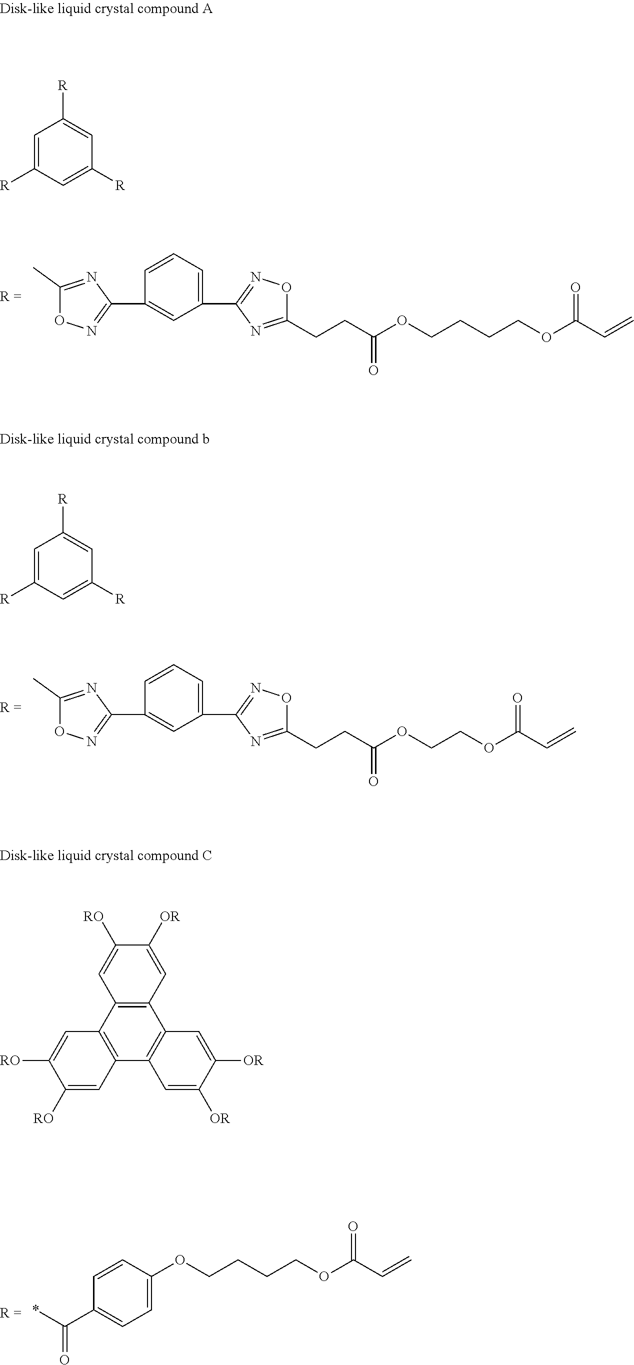

Photo-alignment polymer A (alphabets described in each repeating unit represent the content (% by mass) of each repeating unit with respect to all repeating units, with a being 37% by mass, b being 37% by mass, and c being 26% by mass from the repeating unit on the left. In addition, the weight-average molecular weight was 73,000.)

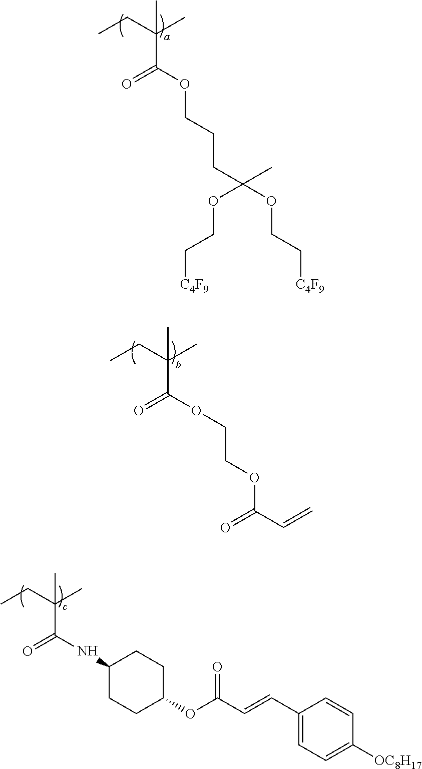

Next, a polymerizable liquid crystal composition NA1 containing a disk-like liquid crystal compound having the following formulation was applied onto the above produced optically anisotropic layer NC1 using a geeser coating machine, and heated with hot air at 95° C. for 120 seconds. Subsequently, the obtained composition layer was irradiated with UV (100 mJ/cm²) at 95° C. to immobilize the alignment of the disk-like liquid crystal compounds, thereby producing an optically anisotropic layer NA1.

The optically anisotropic layer NA1 was a negative A-plate, and had a thickness of 0.55 μm and Re(550) of 55 nm. Assuming that the width direction of the film is defined as 0° (the longitudinal direction of the film is defined as) 90°, the in-plane slow axis direction (alignment axis angle of the liquid crystal compound) was 90°.

Polymerizable liquid crystal composition NA1

| | | |
|---|---|---|
| Disk-like liquid crystal compound A shown above | 80 | parts by mass |
| Disk-like liquid crystal compound B shown above | 20 | parts by mass |
| Alignment film interface alignment agent A | 1.8 | parts by mass |
| shown below | | |
| Ethylene oxide-modified trimethylolpropane | 10.0 | parts by mass |
| triacrylate (V# 360, manufactured by Osaka | | |
| Organic Chemical Industry Ltd.) | | |
| Photopolymerization initiator A shown above | 5.0 | parts by mass |
| Leveling agent B shown below | 0.18 | parts by mass |
| Methyl ethyl ketone | 419 | parts by mass |

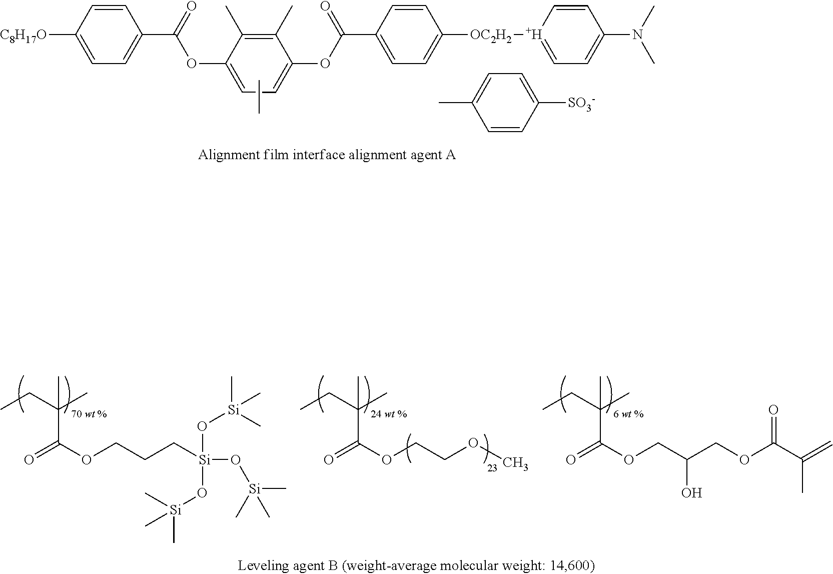

An optical laminate X9 having the optically anisotropic layer NA1 on the optically anisotropic layer NC1 (having a configuration of cellulose-based polymer film/optically anisotropic layer NC1/optically anisotropic layer NA1 in this order) was produced by the above-mentioned procedure.

### (Production of Circular Polarization Plate)

The surface of the optical laminate X9 on the optically anisotropic layer NA1 side (surface opposite to the optically anisotropic layer NC1) was bonded to the TAC film side of the polarizer with a protective film shown in Example 1 using a pressure sensitive adhesive, and then the cellulose-based polymer film on the optically anisotropic layer NC1 side was peeled off to expose the optically anisotropic layer NC1. Subsequently, the coated surface (surface opposite to the optically anisotropic layer C2) of the optically anisotropic layer A8 in the optical laminate X2 produced in Example 15 was bonded to the exposed surface of the optically anisotropic layer NC1 using a pressure sensitive adhesive in a state where the width directions were aligned, and the cellulose-based polymer film on the optically anisotropic layer C2 side was peeled off, thereby obtaining a circular polarization plate composed of optically anisotropic layer C2/optically anisotropic layer A8/pressure sensitive adhesive/optically anisotropic layer NC1/optically anisotropic layer NA1/pressure sensitive adhesive/TAC/polarizer P1/norbornene-based resin film in this order.

The in-plane slow axis of the optically anisotropic layer NA1 was in a direction of 90° with respect to the absorption axis of the polarizer, and the in-plane slow axis of the optically anisotropic layer A8 was in a direction of 45° with respect to the absorption axis of the polarizer.

The in-plane slow axis of the optically anisotropic layer NA1 was at 90° with respect to the absorption axis of the polarizer, and only the optically anisotropic layer A8 did not change the polarization of the emitted light and substantially affected the display performance (oblique tint) of the organic EL display device (substantially functioned as a λ/4 plate), so the Re(600) and Re(440) of the optically anisotropic layer A8 were measured, and the y value was determined to be 1.31.

(Production of organic EL display device)

Using the panel P3 in the organic EL display device of Example 5, the optically anisotropic layer C2 in the above produced circular polarization plate was bonded to the surface of the P/S adjustment layer C of the panel P3 opposite to the PET film through a pressure sensitive adhesive (SK2057, manufactured by Soken Chemical & Engineering Co., Ltd.) such that the optically anisotropic layer C2 was bonded to the P/S adjustment layer C side, thereby producing an organic EL display device of Example 19.

In a case where the organic EL display device of Example 19 was evaluated by the above-mentioned methods, the results were as follows.
x value: 1.54
y value: 1.31
Requirement 1 to Requirement 4: all satisfied (all rated A)
Oblique tint: rated A

### Example 20

(Production of optical laminate X10)

A cellulose-based polymer film (TG40, manufactured by FUJIFILM Corporation) was passed through a dielectric heating roll at a temperature of 60° C. to raise the film surface temperature to 40° C., an alkaline solution having the formulation shown below was applied onto a band surface of the film using a bar coater at a coating amount of 14 mL/m², and the film was then transported for 10 seconds under a steam type far-infrared heater manufactured by Noritake Company Limited that had been heated to 110° C. Subsequently, pure water at an amount of 3 mL/m² was applied thereto using the same bar coater. Then, after washing with water using a fountain coater and draining using an air knife were repeated three times, the film was transported to a drying zone at 70° C. for 10 seconds and dried to produce a cellulose acylate film which had been subjected to an alkali saponification treatment.

Alkaline solution

| | | |
|---|---|---|
| Potassium hydroxide | 4.7 | parts by mass |
| Water | 15.8 | parts by mass |
| Isopropanol | 63.7 | parts by mass |
| Surfactant: C₁₄H₂₉O(CH₂CH₂O)₂₀H | 1.0 | parts by mass |
| Propylene glycol | 14.8 | parts by mass |

### (Formation of Alignment Film)

An alignment film coating liquid 1 having the following formulation was continuously applied onto the alkali saponification-treated surface of the cellulose acylate film using a #14 wire bar. Then, the obtained coating film was dried with hot air at 60° C. for 60 seconds and further with hot air at 100° C. for 120 seconds to obtain an alignment film.

Alignment film coating liquid 1

| | | |
|---|---|---|
| Polyvinyl alcohol (PVA-203, | 28 | parts by mass |
| manufactured by Kuraray Co., Ltd.) | | |
| Citric acid ester (AS3, | 1.2 | parts by mass |
| manufactured by Sankyo Chemical Co., Ltd.) | | |
| Glutaraldehyde | 2.8 | parts by mass |
| Water | 699 | parts by mass |
| Methanol | 226 | parts by mass |

The above produced alignment film was continuously subjected to a rubbing treatment. At this time, the longitudinal direction and the transport direction of the elongated film (cellulose acylate film) were parallel to each other, and the angle formed between the film longitudinal direction (transport direction) and the rubbing roller rotation axis was 90°.

A polymerizable liquid crystal composition NA2 containing a disk-like liquid crystal compound having the following formulation was applied onto the rubbing-treated alignment film using a geeser coating machine to form a composition layer. Thereafter, the obtained composition layer was heated with hot air at 110° C. for 2 minutes for drying of the solvent and alignment aging of the disk-like liquid crystal compound. Subsequently, the obtained composition layer was irradiated with UV (500 mJ/cm²) at 80° C. to immobilize the alignment of the disk-like liquid crystal compound to form an optically anisotropic layer NA2, thereby producing an optical laminate X10 (having a configuration of cellulose-based polymer film/alignment film/optically anisotropic layer NA2 in this order).

The optically anisotropic layer NA2 was a negative A-plate, and had a thickness of 0.55 μm and Re(550) of 55 nm. Assuming that the width direction of the film is defined as 0° (the longitudinal direction of the film is defined as) 90°, the in-plane slow axis direction (alignment axis angle of the liquid crystal compound) was 90°.

Polymerizable liquid crystal composition NA2

| | | |
|---|---|---|
| Disk-like liquid crystal compound A shown | 80 | parts by mass |
| above | | |
| Disk-like liquid crystal compound B shown | 20 | parts by mass |
| above | | |
| Alignment film interface alignment agent A | 0.55 | parts by mass |
| shown above | | |
| Leveling agent B shown above | 0.1 | parts by mass |
| Ethylene oxide-modified trimethylolpropane | 10 | parts by mass |
| triacrylate (V#360, manufactured by Osaka | | |
| Organic Chemical Industry Ltd.) | | |
| Photopolymerization initiator | 3.0 | parts by mass |
| (IRGACURE 907, manufactured by BASF SE) | | |
| Methyl ethyl ketone | 200 | parts by mass |

### (Production of Optical Laminate X11)

An optical laminate X11 having an optically anisotropic layer A12 on an optically anisotropic layer C6 was produced in the same manner as in the optical laminate in Example 1, except that the thickness of the optically anisotropic layer C1 was changed to 0.15 μm.

The optically anisotropic layer C6 was a positive C-plate, and had Re(550) of 0 nm and Rth(550) of −15 nm, and the optically anisotropic layer A12 was a positive A-plate, and had Re(550) of 141 nm and Rth(550) of 70.5 nm.

### (Production of Circular Polarization Plate)

The surface of the optical laminate X10 on the optically anisotropic layer NA2 side (surface opposite to the alignment film) was bonded to the TAC film side of the polarizer with a protective film shown in Example 1 using a pressure sensitive adhesive, and then the cellulose-based polymer film and the alignment film on the optically anisotropic layer NA2 side were peeled off. The coating surface (surface opposite to the optically anisotropic layer C6) of the optically anisotropic layer A12 in the above produced optical laminate X11 was bonded to the surface of the exposed optically anisotropic layer NA2 using a pressure sensitive adhesive in a state where the width directions were aligned, and the cellulose-based polymer film on the optically anisotropic layer C6 side was peeled off, thereby obtaining a circular polarization plate composed of optically anisotropic layer C6/optically anisotropic layer A12/pressure sensitive adhesive/optically anisotropic layer NA2/pressure sensitive adhesive/TAC/polarizer P1/norbornene-based resin film in this order.

The in-plane slow axis of the optically anisotropic layer NA2 was in a direction of 90° with respect to the absorption axis of the polarizer, and the in-plane slow axis of the optically anisotropic layer A12 was in a direction of 45° with respect to the absorption axis of the polarizer.

The in-plane slow axis of the optically anisotropic layer NA2 was at 90° with respect to the absorption axis of the polarizer, and only the optically anisotropic layer A12 did not change the polarization of the emitted light and substantially affected the display performance (oblique tint) of the organic EL display device (substantially functioned as a λ/4 plate), so the Re(600) and Re(440) of the optically anisotropic layer A12 were measured, and the y value was determined to be 1.31.

### (Production of Organic EL Display Device)

Using the panel P3 in the organic EL display device of Example 5, the optically anisotropic layer C6 in the above produced circular polarization plate was bonded to the surface of the P/S adjustment layer C of the panel P3 opposite to the PET film through a pressure sensitive adhesive (SK2057, manufactured by Soken Chemical & Engineering Co., Ltd.) such that the optically anisotropic layer C6 was bonded to the P/S adjustment layer C side, thereby producing an organic EL display device of Example 20.

In a case where the organic EL display device of Example 20 was evaluated by the above-mentioned methods, the results were as follows.
x value: 1.54
y value: 1.31
Requirement 1 to Requirement 4: all satisfied (all rated A)
Oblique tint: rated A

### Example 21

### (Production of Optical Laminate X12)

An optical laminate X12 having an optically anisotropic layer NA3 on an optically anisotropic layer NC2 (having a configuration of cellulose-based polymer film/optically anisotropic layer NC2/optically anisotropic layer NA3 in this order) was produced in the same manner as in the optical laminate X9 of Example 19, except that the thickness of the optically anisotropic layer NC1, and the in-plane slow axis direction (alignment axis angle of the liquid crystal compound) and the thickness of the optically anisotropic layer NA1 were changed as follows.

The optically anisotropic layer NC2 was a negative C-plate, and had a thickness of 0.4 μm, Re(550) of 0 nm, and Rth(550) of 40 nm.

The optically anisotropic layer NA3 was a negative A-plate, and had a thickness of 0.45 μm and Re(550) of 45 nm. Assuming that the width direction of the film is defined as 0° (the longitudinal direction of the film is defined as) 90°, the in-plane slow axis direction (alignment axis angle of the liquid crystal compound) was −45°.

### (Production of Optical Laminate X13)

An optical laminate X13 having an optically anisotropic layer A13 on an optically anisotropic layer C7 was produced in the same manner as in the optical laminate of Example 1, except that the thickness of the optically anisotropic layer C1 was changed to 1.1 μm and the thickness of the optically anisotropic layer A1 was changed to 3.0 μm.

The optically anisotropic layer C7 was a positive C-plate, and had Re(550) of 0 nm and Rth(550) of −110 nm, and the optically anisotropic layer A13 was a positive A-plate, and had Re(550) of 185 nm and Rth(550) of 92.5 nm.

### (Production of Circular Polarization Plate)

A circular polarization plate composed of optically anisotropic layer C7/optically anisotropic layer A13/pressure sensitive adhesive/optically anisotropic layer NC2/optically anisotropic layer NA3/pressure sensitive adhesive/TAC/polarizer P1/norbornene-based resin film in this order was obtained in the same manner as in Example 19, except that the optical laminate X12 was used instead of the optical laminate X9, and the optical laminate X13 was used instead of the optical laminate X2.

The in-plane slow axis of the optically anisotropic layer NA3 was in a direction of −45° with respect to the absorption axis of the polarizer, and the in-plane slow axis of the optically anisotropic layer A13 was in a direction of 45° with respect to the absorption axis of the polarizer. In a case where Re(600) and Re(440) of the laminate of the optically anisotropic layer A13 and the optically anisotropic layer NA3 were measured, the y value was determined to be 1.30.

### (Production of Organic EL Display Device)

Using the panel P3 in the organic EL display device of Example 5, the optically anisotropic layer C7 in the above produced circular polarization plate was bonded to the surface of the P/S adjustment layer C of the panel P3 opposite to the PET film through a pressure sensitive adhesive (SK2057, manufactured by Soken Chemical & Engineering Co., Ltd.) such that the optically anisotropic layer C7 was bonded to the P/S adjustment layer C side, thereby producing an organic EL display device of Example 21.

In a case where the organic EL display device of Example 21 was evaluated by the above-mentioned methods, the results were as follows.
x value: 1.54
y value: 1.30
Requirement 1 to Requirement 4: all satisfied (all rated A)
Oblique tint: rated A

### Example 22

### (Production of Optical Laminate X14)

An optical laminate X14 having an optically anisotropic layer NA4 (having a configuration of cellulose-based polymer film/alignment film/optically anisotropic layer NA4 in this order) was produced in the same manner as in the optical laminate X10 of Example 20, except that the in-plane slow axis direction (alignment axis angle of liquid crystal compound) and the thickness of the optically anisotropic layer NA2 were changed as follows.

The optically anisotropic layer NA4 was a negative A-plate, and had a thickness of 0.45 μm and Re(550) of 45 nm. Assuming that the width direction of the film is defined as 0° (the longitudinal direction of the film is defined as) 90°, the in-plane slow axis direction (alignment axis angle of the liquid crystal compound) was −45°.

### (Production of Optical Laminate X15)

An optical laminate X15 having an optically anisotropic layer A14 on an optically anisotropic layer C8 was produced in the same manner as in the optical laminate in Example 1, except that the thickness of the optically anisotropic layer C1 was changed to 0.80 μm and the thickness of the optically anisotropic layer A1 was changed to 3.0 μm.

The optically anisotropic layer C8 was a positive C-plate, and had Re(550) of 0 nm and Rth(550) of −70 nm, and the optically anisotropic layer A14 was a positive A-plate, and had Re(550) of 180 nm and Rth(550) of 185 nm.

### (Production of Circular Polarization Plate)

A circular polarization plate composed of optically anisotropic layer C8/optically anisotropic layer A14/pressure sensitive adhesive/optically anisotropic layer NA4/pressure sensitive adhesive/TAC/polarizer P1/norbornene-based resin film in this order was obtained in the same manner as in Example 20, except that the optical laminate X14 was used instead of the optical laminate X10 and the optical laminate X15 was used instead of the optical laminate X11.

The in-plane slow axis of the optically anisotropic layer NA4 was in a direction of −45° with respect to the absorption axis of the polarizer, and the in-plane slow axis of the optically anisotropic layer A14 was in a direction of 45° with respect to the absorption axis of the polarizer. In a case where Re(600) and Re(440) of the laminate of the optically anisotropic layer A14 and the optically anisotropic layer NA4 were measured, the y value was determined to be 1.30.

### (Production of Organic EL Display Device)

Using the panel P3 in the organic EL display device of Example 5, the optically anisotropic layer C8 in the above produced circular polarization plate was bonded to the surface of the P/S adjustment layer C of the panel P3 opposite to the PET film through a pressure sensitive adhesive (SK2057, manufactured by Soken Chemical & Engineering Co., Ltd.) such that the optically anisotropic layer C8 was bonded to the P/S adjustment layer C side, thereby producing an organic EL display device of Example 22.

In a case where the organic EL display device of Example 22 was evaluated by the above-mentioned methods, the results were as follows.
x value: 1.54
y value: 1.30
Requirement 1 to Requirement 4: all satisfied (all rated A)
Oblique tint: rated A

### EXPLANATION OF REFERENCES

10: organic EL display device
20: circular polarization plate
22: polarizer
24: optically anisotropic layer
30: organic EL display element
32: polarization adjustment layer
34: organic EL substrate

What is claimed is:

1. An organic electroluminescent display device comprising:
a circular polarization plate; and
an organic electroluminescent display element,
wherein the circular polarization plate includes an optically anisotropic layer and a polarizer from an organic electroluminescent display element side, and
in a case where a ratio of brightness of P-polarized light to brightness of S-polarized light during white display of the organic electroluminescent display element in a direction in which a polar angle with respect to a normal direction of the organic electroluminescent display element is 60° is determined at each azimuthal angle rotated by 45° with reference to a direction parallel to a transmission axis of the polarizer, an arithmetic mean value of the ratios of the brightness of the P-polarized light to the brightness of the S-polarized light at the azimuthal angles is defined as x, and the arithmetic mean value x is 1.00 or more, and
a ratio of an in-plane retardation at a wavelength of 600 nm to an in-plane retardation at a wavelength of 440 nm in the optically anisotropic layer is defined as y,
the organic electroluminescent display device satisfies Requirement 1 and Requirement 2,
$$y \leq - 0.155 x + 1.655 \qquad Requirement 1$$
$$y \geq 0. 170 x + 0.980 \qquad Requirement 2$$
the ratio of the brightness of the P-polarized light to the brightness of the S-polarized light is an arithmetic mean value of ratios of the brightness of the P-polarized light to the brightness of the S-polarized light at each wavelength at intervals of 10 nm in a wavelength range of 420 to 680 nm.

2. The organic electroluminescent display device according to claim 1,
wherein the organic electroluminescent display device satisfies Requirement 3 and Requirement 4,
$$y \leq - 0.240 x + 1.74 \qquad Requirement 3$$
$$y \geq 0.26 x + 0.8 90. \qquad Requirement 4$$

3. The organic electroluminescent display device according to claim 1,
wherein the optically anisotropic layer is a λ/4 plate.
